(19) United States
(12) Patent Application Publication
(10) Pub. No.: US 2025/0113614 A1
(43) Pub. Date: Apr. 3, 2025

(54) ARRAY SUBSTRATE, DISPLAY PANEL AND DISPLAY DEVICE

(71) Applicants: FUZHOU BOE OPTOELECTRONICS TECHNOLOGY CO., LTD., Fuzhou (CN); BOE TECHNOLOGY GROUP CO., LTD., Beijing (CN)

(72) Inventors: Shanshan XU, Beijing (CN); Xu XU, Beijing (CN); Yao LIU, Beijing (CN); Jinfeng CHEN, Beijing (CN); Jin WANG, Beijing (CN); Hao CHENG, Beijing (CN)

(21) Appl. No.: 18/559,409

(22) PCT Filed: Jan. 18, 2023
(86) PCT No.: PCT/CN2023/072975

§ 371 Date: Nov. 7, 2023

(51) Int. Cl. H10D 86/40; H10D 86/60

(52) U.S. Cl. CPC H10D 86/443; H10D 86/60

(57) ABSTRACT

An array substrate, a display panel and a display device are provided. The array substrate includes sub-pixels, common electrode lines, a common signal transmission line and fanout wiring regions. The sub-pixels are located in the display region, and include a common electrode; the common electrode lines are electrically connected with the common electrode of the sub-pixels, and the common signal transmission line is disposed in the non-display region and electrically connected with the common electrode lines. A wire located in the fanout wiring region at an edge is electrically connected with the common signal transmission line, a conductive structure is disposed between the fanout wiring region and the common signal transmission line, the conductive structure is electrically connected with a wire located at an edge in the fanout wiring region, and the conductive structure is separated from the common signal transmission line.

### TECHNICAL FIELD

Embodiments of the present disclosure relate to an array substrate, a display panel and a display device.

### BACKGROUND

With the development of display products, the transmittance of display products has become an important factor in its competitiveness. In the pixel design of a display product, the common electrode line design for transverse transmission of common signals is omitted; and compared with the traditional pixel design, the transmittance of this display product can be increased by more than 5%, and the display effect of the product is improved.

### SUMMARY

The present disclosure provides an array substrate, a display panel and a display device.

An embodiment of the present disclosure provides an array substrate, which includes an array substrate including a display region and a non-display region located on at least one side of the display region. The array substrate includes a plurality of sub-pixels, a plurality of common electrode lines, a common signal transmission line, and a plurality of fanout wiring regions. At least part of the plurality of sub-pixels is located in the display region, and the sub-pixels located in the display region include a common electrode; the plurality of common electrode lines are located in the display region and electrically connected with the common electrode of the sub-pixels, the plurality of common electrode lines is arranged along a first direction; the common signal transmission line is disposed in the non-display region and electrically connected with the plurality of common electrode lines; the plurality of fanout wiring regions are located in the non-display region and arrange along the first direction. Among the plurality of fanout wiring regions, a wire located in the fanout wiring region at an edge in the first direction is electrically connected with the common signal transmission line, a conductive structure is disposed between at least one fanout wiring region and the common signal transmission line, the conductive structure is electrically connected with a wire located at an edge in the at least one fanout wiring region, and the conductive structure is separated from the common signal transmission line.

For example, according to an embodiment of the present disclosure, a count of conductive structures is plural, a plurality of conductive structures is arranged along the first direction, and at least one conductive structure is electrically connected with two parts of wires, close to each other, in two adjacent fanout wiring regions.

For example, according to an embodiment of the present disclosure, the array substrate further includes: an electrostatic discharge structure, located in the non-display region and between the common signal transmission line and the plurality of fanout wiring regions. The conductive structure is electrically connected with the electrostatic discharge structure, and the conductive structure is coupled to the common signal transmission line.

For example, according to an embodiment of the present disclosure, the array substrate further includes: a base substrate; a plurality of gate lines, located on the base substrate and arranged along a second direction, the second direction intersects with the first direction; a plurality of data lines, located on the base substrate and arranged along the first direction, the plurality of data lines is located at one side of the plurality of gate lines away from the base substrate, and the common electrode is located at one side of the plurality of data lines away from the base substrate. The sub-pixel located in the display region further includes a switching structure and a pixel electrode, and the switching structure includes three electrodes electrically connected with the gate line, the data line and the pixel electrode, respectively; the common signal transmission line includes a first transmission portion extending in the first direction and located between the display region and the plurality of fanout wiring regions, the first transmission portion includes a first conductive layer and a second conductive layer which are stacked, the first conductive layer is disposed in the same layer as the gate line, and the second conductive layer is disposed in the same layer as the common electrode.

For example, according to an embodiment of the present disclosure, a count of the plurality of fanout wiring regions is N, a length of the first transmission portion is L, and a resistance of a part, with a length of L/2N, of the first transmission portion is not greater than 30 ohms, where N is a positive integer.

For example, according to an embodiment of the present disclosure, the plurality of common electrode lines is electrically connected with the first transmission portion through a plurality of connection blocks, and the plurality of connection blocks is disposed in the same layer as the plurality of data lines; in a direction perpendicular to the base substrate, the plurality of connection blocks does not overlap with the first conductive layer, and the plurality of connection blocks is electrically connected with the first conductive layer through the second conductive layer.

For example, according to an embodiment of the present disclosure, the plurality of common electrode lines is electrically connected with the first transmission portion through a plurality of connection blocks, an orthographic projection of the plurality of connection blocks on the base substrate falls within an orthographic projection of the first conductive layer on the base substrate, and the plurality of connection blocks is electrically connected with the first conductive layer through the second conductive layer.

For example, according to an embodiment of the present disclosure, the first transmission portion includes a first edge and a second edge extending in the first direction, the first edge is located at one side of the second edge close to the display region, and a distance between the connection block and the second edge is less than a distance between the connection block and the first edge.

For example, according to an embodiment of the present disclosure, the common signal transmission line further includes a second transmission portion extending in the second direction, the second transmission portion includes a third conductive layer and a fourth conductive layer which are stacked, the third conductive layer is disposed in the same layer as the plurality of data lines, the third conductive layer and the first conductive layer are an integrated film layer, and the fourth conductive layer is disposed in the same layer as the common electrode.

For example, according to an embodiment of the present disclosure, the plurality of sub-pixels is arrayed along the first direction and the second direction, two sub-pixel columns arranged along the first direction are disposed between adjacent data lines, sub-pixels in each sub-pixel column are arranged along the second direction, different sub-pixels connected with a same data line are connected with different gate lines, the plurality of gate lines includes first gate lines and second gate lines alternately arranged along the second direction, and a gate line pair formed by the first gate line and the second gate line is disposed between two adjacent sub-pixels arranged along the second direction; and the plurality of data lines and the plurality of common electrode lines are alternately arranged along the first direction.

Another embodiment of the present disclosure provides an array substrate, including a display region and a non-display region located on at least one side of the display region, the array substrate includes: a plurality of sub-pixels, a plurality of common electrode lines, a common signal transmission line, a plurality of fanout wiring regions and a plurality of first connection structures. At least part of the plurality of sub-pixels is located in the display region, and the sub-pixels located in the display region include a common electrode; the plurality of common electrode lines are located in the display region and electrically connected with the common electrode of the sub-pixels, the plurality of common electrode lines is arranged along a first direction; the common signal transmission line is disposed in the non-display region and electrically connected with the plurality of common electrode lines; the plurality of fanout wiring regions are located in the non-display region and arrange along the first direction; the plurality of first connection structures are located between the common signal transmission line and the plurality of fanout wiring regions, the plurality of first connection structures is arranged along the first direction. Wires in at least part of the plurality of fanout wiring regions are electrically connected with the common signal transmission line through the plurality of first connection structures; a count of the plurality of fanout wiring regions is N, the common signal transmission line includes a first transmission portion extending in the first direction and located between the display region and the plurality of fanout wiring regions, a length of the first transmission portion is L, and a resistance of a part, with a length of L/2N, of the first transmission portion is not greater than 30 ohms, where N is a positive integer.

For example, according to an embodiment of the present disclosure, the array substrate further includes: a base substrate; a plurality of gate lines, located on the base substrate and arranged along a second direction, the second direction intersecting with the first direction; a plurality of data lines, located on the base substrate and arranged along the first direction, wherein the plurality of data lines is located at one side of the plurality of gate lines away from the base substrate, and the common electrode is located at one side of the plurality of data lines away from the base substrate. The sub-pixel located in the display region further includes a switching structure and a pixel electrode, and the switching structure includes three electrodes electrically connected with the gate line, the data line and the pixel electrode, respectively; the first transmission portion includes a first conductive layer and a second conductive layer which are stacked, the first conductive layer is disposed in the same layer as the gate line, and the second conductive layer is disposed in the same layer as the common electrode.

For example, according to an embodiment of the present disclosure, the plurality of common electrode lines is electrically connected with the first transmission portion through a plurality of connection blocks, the plurality of connection blocks do not overlap with the first conductive layer in a direction perpendicular to the base substrate, and the plurality of connection blocks is electrically connected with the first conductive layer through the second conductive layer.

For example, according to an embodiment of the present disclosure, the plurality of common electrode lines is electrically connected with the first transmission portion through a plurality of connection blocks, and the plurality of connection blocks is arranged in the same layer as the plurality of data lines; an orthographic projection of the plurality of connection blocks on the base substrate falls within an orthographic projection of the first conductive layer on the base substrate, and the plurality of connection blocks is electrically connected with the first conductive layer through the second conductive layer.

For example, according to an embodiment of the present disclosure, the first transmission portion includes a first edge and a second edge extending in the first direction, the first edge is located at one side of the second edge close to the display region, and a distance between the connection block and the second edge is less than a distance between the connection block and the first edge.

For example, according to an embodiment of the present disclosure, the common signal transmission line further includes a second transmission portion extending in the second direction, the second transmission portion includes a third conductive layer and a fourth conductive layer which are stacked, the third conductive layer and the first conductive layer are an integrated film layer, and the fourth conductive layer and the second conductive layer are an integrated film layer.

For example, according to an embodiment of the present disclosure, the plurality of sub-pixels is arrayed along the first direction and the second direction, two sub-pixel columns arranged along the first direction are disposed between adjacent data lines, sub-pixels in each sub-pixel column are arranged along the second direction, different sub-pixels connected with a same data line are connected with different gate lines, the plurality of gate lines includes first gate lines and second gate lines alternately arranged along the second direction, and a pair of gate lines formed by the first gate line and the second gate line is disposed between two adjacent sub-pixels arranged along the second direction; and the plurality of data lines and the plurality of common electrode lines are alternately arranged along the first direction.

For example, according to an embodiment of the present disclosure, each fanout wiring region includes a middle region and edge regions located at both sides of the middle region in the first direction, and the plurality of first connection structures is electrically connected with wires in the edge region of at least part of the plurality of fanout wiring regions; the array substrate further includes a plurality of second connection structures located between the common signal transmission line and the plurality of fanout wiring regions, and the plurality of second connection structures is arranged along the first direction; wires in the middle region of at least part of the plurality of fanout wiring regions are electrically connected with the common signal transmission line through the plurality of second connection structures.

For example, according to an embodiment of the present disclosure, each fanout wiring region includes a middle region and edge regions located at both sides of the middle region in the first direction, and the plurality of first connection structures is electrically connected with wires in the edge region of at least part of the plurality of fanout wiring regions; and at least one first connection structure is electrically connected with wires in two edge regions, close to each other, of two adjacent fanout wiring regions.

For example, according to an embodiment of the present disclosure, the array substrate further includes: an electrostatic discharge structure, located in the non-display region and between the common signal transmission line and the plurality of fanout wiring regions, wherein the electrostatic discharge structure includes a plurality of electrostatic discharge unit groups, each electrostatic discharge unit group includes a plurality of electrostatic discharge units and a connection wire connecting the plurality of electrostatic discharge units, and at least part of the plurality of electrostatic discharge units is electrically connected with the plurality of data lines. The plurality of first connection structures passes through gaps between the plurality of electrostatic discharge unit groups so as to be electrically connected with the common signal transmission line, and/or the plurality of second connection structures passes through gaps between the plurality of electrostatic discharge units so as to be electrically connected with the common signal transmission line; and at least one of the plurality of first connection structures is electrically connected with the electrostatic discharge structure.

For example, according to an embodiment of the present disclosure, two electrostatic discharge units located at both sides of each second connection structure and adjacent to the each second connection structure are electrically connected with the data line.

For example, according to an embodiment of the present disclosure, the first connection structure, the second connection structure and the first conductive layer of the common signal transmission line are an integrated structure; the connection wire is disposed in the same layer as the first conductive layer of the common signal transmission line, and the connection wire is spaced apart from the second connection structure.

For example, according to an embodiment of the present disclosure, the first connection structure and the first conductive layer of the common signal transmission line are an integrated structure, and the connection wire is disposed in the same layer as the first conductive layer of the common signal transmission line; in a direction perpendicular to the base substrate, the second connection structure overlaps with the connection wire, and the second connection structure overlaps with the common signal transmission line, and the second connection structure is electrically connected with the common signal transmission line through a via in an insulating layer between the second connection structure and the common signal transmission line.

Another embodiment of the present disclosure provides an array substrate, which includes a display region and a non-display region located on at least one side of the display region. The array substrate includes: a plurality of sub-pixels, a plurality of common electrode lines, a plurality of common electrode lines, a fanout wiring region, and a plurality of connection structures. At least part of the plurality of sub-pixels is located in the display region, and the sub-pixels located in the display region include a common electrode; the plurality of common electrode lines is located in the display region and electrically connected with the common electrode of the sub-pixels, the plurality of common electrode lines is arranged along a first direction; the common signal transmission line is disposed in the non-display region and electrically connected with the plurality of common electrode lines; the fanout wiring region is located in the non-display region; the plurality of connection structures is located between the common signal transmission line and the fanout wiring region, the plurality of connection structures is arranged along the first direction. The fanout wiring region includes a middle region and edge regions located at both sides of the middle region in the first direction; a wire in the middle region of the fanout wiring region is electrically connected with the common signal transmission line through at least one connection structure among the plurality of connection structures.

For example, according to an embodiment of the present disclosure, the fanout wiring region includes a plurality of fanout wiring regions, and each fanout wiring region includes the middle region and the edge regions; the plurality of connection structures include a plurality of first connection structures and a plurality of second connection structures, the plurality of first connection structures is arranged along the first direction, the plurality of second connection structures is arranged along the first direction, the plurality of first connection structures is electrically connected with wires in the edge region of at least part of the plurality of fanout wiring regions, and wires in the middle region of at least part of the plurality of fanout wiring regions are electrically connected with the common signal transmission line through the plurality of second connection structures.

For example, according to an embodiment of the present disclosure, at least one first connection structure is electrically connected with wires in two edge regions, close to each other, of two adjacent fanout wiring regions.

For example, according to an embodiment of the present disclosure, the array substrate further includes: a base substrate; a plurality of gate lines, located on the base substrate and arranged along a second direction, wherein the second direction intersects with the first direction; a plurality of data lines, located on the base substrate and arranged along the first direction, wherein the plurality of data lines is located at one side of the plurality of gate lines away from the base substrate, and the common electrode is located at one side of the plurality of data lines away from the base substrate; an electrostatic discharge structure, located in the non-display region and between the common signal transmission line and the plurality of fanout wiring regions, wherein the electrostatic discharge structure includes a plurality of electrostatic discharge unit groups, each electrostatic discharge unit group includes a plurality of electrostatic discharge units and a connection wire connecting the plurality of electrostatic discharge units, and at least part of the plurality of electrostatic discharge units is electrically connected with the plurality of data lines. The sub-pixel located in the display region further includes a switching structure and a pixel electrode, and the switching structure includes three electrodes electrically connected with the gate line, the data line and the pixel electrode, respectively; the plurality of first connection structures passes through gaps between the plurality of electrostatic discharge unit groups so as to be electrically connected with the common signal transmission line, and the plurality of second connection structures pass through gaps between the plurality of electrostatic discharge units so as to be electrically connected with the common signal transmission line; and at least one of the plurality of first connection structures is electrically connected with the electrostatic discharge structure.

For example, according to an embodiment of the present disclosure, two electrostatic discharge units located at both sides of each second connection structure and adjacent to the each second connection structure are electrically connected with the data line.

For example, according to an embodiment of the present disclosure, wires in each fanout wiring region are electrically connected with one electrostatic discharge unit group, and at least one second connection structure is disposed in a plurality of gaps between the plurality of electrostatic discharge units in at least one electrostatic discharge unit group.

For example, according to an embodiment of the present disclosure, the common signal transmission line includes a first transmission portion extending in the first direction and located between the display region and the plurality of fanout wiring regions, the first transmission portion includes a first conductive layer and a second conductive layer which are stacked, the first conductive layer is disposed in the same layer as the gate line, and the second conductive layer is disposed in the same layer as the common electrode.

For example, according to an embodiment of the present disclosure, the first connection structure, the second connection structure and the first conductive layer of the common signal transmission line are an integrated structure; the connection wire is disposed in the same layer as the first conductive layer of the common signal transmission line, and the connection wire is spaced apart from the second connection structure.

For example, according to an embodiment of the present disclosure, the first connection structure and the first conductive layer of the common signal transmission line are an integrated structure, and the connection wire is disposed in the same layer as the first conductive layer of the common signal transmission line; in a direction perpendicular to the base substrate, the second connection structure overlaps with the common signal transmission line, and the second connection structure is electrically connected with the common signal transmission line through a via in an insulating layer between the second connection structure and the common signal transmission line.

For example, according to an embodiment of the present disclosure, the second connection structure overlaps with the connection wire in the direction perpendicular to the base substrate.

For example, according to an embodiment of the present disclosure, the plurality of common electrode lines is electrically connected with the common signal transmission line through a plurality of connection blocks, and the plurality of connection blocks is disposed in the same layer as the plurality of data lines; and at least one second connection structure and the connection block are integrated.

For example, according to an embodiment of the present disclosure, a count of the plurality of fanout wiring regions is N, the common signal transmission line includes a first transmission portion extending in the first direction and located between the display region and the plurality of fanout wiring regions, a length of the first transmission portion is L, and a resistance of a part, with a length of L/2N, of the first transmission portion is not greater than 30 ohms, where N is a positive integer.

An embodiment of the present disclosure provides a display panel, including any array substrate as mentioned above.

An embodiment of the present disclosure provides a display device, including the display panel as mentioned above.

An embodiment of the present disclosure provides a display device, including a first circuit board, a second circuit board and the array substrate including the first connection structure as mentioned above. The second circuit board is electrically connected with the array substrate through the first circuit board, a common signal connection line and a zero-ohm resistor are disposed on the second circuit board, the zero-ohm resistor is electrically connected with the common signal connection line, and the common signal connection line is electrically connected with the first connection structure.

An embodiment of the present disclosure provides a display device, including a first circuit board, a second circuit board and the array substrate including the connection structure as mentioned above. The second circuit board is electrically connected with the array substrate through the first circuit board, and a common signal connection line and a zero-ohm resistor are disposed on the second circuit board, the zero-ohm resistor is electrically connected with the common signal connection line, and the common signal connection line is electrically connected with the connection structure.

### BRIEF DESCRIPTION OF DRAWINGS

In order to clearly illustrate the technical solution of the embodiments of the invention, the drawings of the embodiments will be briefly described in the following; it is obvious that the described drawings are only related to some embodiments of the present disclosure and thus are not limitative of the present disclosure.

FIG. 1 is a partial structural view of a display device.

FIG. 2 is a partial structural view of an array substrate provided by an embodiment of the present disclosure.

FIG. 3 is a partial structural view of the display region shown in FIG. 2.

FIG. 4 is an enlarged view of region A of the array substrate shown in FIG. 2.

FIG. 5 is a circuit diagram of an electrostatic discharge unit of the electrostatic discharge structure shown in FIG. 4.

FIG. 6 is a circuit diagram of two electrostatic discharge unit groups shown in FIG. 4.

FIG. 7 is an enlarged view of region A of the array substrate shown in FIG. 2 in another example.

FIG. 8 is a partial cross-sectional structural view taken along line BB′ shown in FIG. 7.

FIG. 9 is a partial planar structural view of the array substrate shown in FIG. 2 in another example.

FIG. 10 is a partial cross-sectional structural view taken along line CC′ shown in FIG. 9.

FIGS. 11 and 12 are partial planar structural views of the array substrate shown in FIG. 2 in different examples.

FIG. 13 is a partial planar structural view of an array substrate provided by another embodiment of the present disclosure.

FIG. 14 is a partial structural view of region D shown in FIG. 13.

FIG. 15A is a partial structural view of region E1 shown in FIG. 13.

FIG. 15B is a partial structural view of region E2 shown in FIG. 13.

FIG. 15C is a partial structural view of region E3 shown in FIG. 13.

FIG. 16 is a partial planar structural view of an array substrate provided by another example of the embodiment of the present disclosure.

FIGS. 17 and 18 are partial enlarged views of region F shown in FIG. 16 in different examples.

FIG. 19 is a circuit diagram of an electrostatic discharge unit group shown in FIG. 17.

FIG. 20 is a circuit diagram of an electrostatic discharge unit group shown in FIG. 18.

FIG. 21 is a circuit diagram of an electrostatic discharge unit group shown in another example.

FIG. 22 is a partial planar structural view of an array substrate provided by another embodiment of the present disclosure.

FIG. 23 is a partial enlarged view of region G1 in the array substrate shown in FIG. 22.

FIG. 24 is a partial enlarged view of region G2 in the array substrate shown in FIG. 22.

FIG. 25 is a partial enlarged view of region G3 in the array substrate shown in FIG. 22.

FIG. 26 is a partial enlarged view of region H1 of the array substrate shown in FIG. 22 in an example.

FIG. 27 is a partial enlarged view of region H2 of the array substrate shown in FIG. 22.

FIG. 28 is a partial enlarged view of region H3 of the array substrate shown in FIG. 22.

FIG. 29 is a partial enlarged view of region H1 of the array substrate shown in FIG. 22 in another example.

FIG. 30 is a partial structural view of a display device according to another embodiment of the present disclosure.

FIG. 31 is a timing chart of a data signal and a gate signal in the array substrate.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. In the embodiment of the present disclosure, the features, “parallel to,” “perpendicular to,” “identical to,” etc., all include the features “parallel to,” “perpendicular to,” “identical to,” etc., in the strict sense, as well as the cases containing certain errors, such as “approximately parallel to,” “approximately perpendicular to,” “approximately identical to,” etc. Considering the measurement and the errors related to the measurement of a specific quantity (e.g., the limitation of the measurement system), they are within an acceptable deviation range for the specific quantity determined by those skilled in the art. For example, the term “approximately” can mean within one or more standard deviations, or within 10% or 5% deviation of the stated value. When the quantity of a component is not specified in the following description of the embodiments of the present disclosure, it means that the number of the components can be one or more, or can be understood as at least one. The phrase “at least one” means one or more, and the phrase “plurality of” means at least two. The feature “in a same layer” in the present disclosure refers to that two (or more than two) structures are formed by patterning through a same deposition process and a same patterning process, and they can have the same or different materials. The feature “being an integrated structure” in the present disclosure refers to that two (or more than two) structures connected to each other are formed by patterning through a same deposition process and a same patterning process, and they can have the same or different materials.

In research, the inventor(s) of the present application have noticed that in a dual-gate type display device, in the case where two gate lines are disposed between two adjacent rows of sub-pixels and no common electrode line extending transversely is disposed, the metal wire and the space can be saved and the transmittance can be improved, but the common signal delay of the display device is large.

In the test of the display device, in one picture, only data signals with the same polarity are input in one frame, so the coupling of the common voltage (Vcom) within one frame by the data lines is also the greatest. In the case where the common signal delay of the display device is relatively large, the coupling of the common voltage within one frame may not be restored, which will eventually lead to the difference in brightness and darkness on the display. For example, upon the display device being in a Flicker Pattern, the coupling recovery of the common voltage is different at different positions. In the case where the display panel is electrically connected with a plurality of flexible printed circuit boards (e.g., Chip on film, COF), the corresponding common signal transmission line between adjacent flexible printed circuit board is provided with a common signal compensation point, and the coupling recovery time of the common voltage at the compensation point is shorter than that at other positions, which easily leads to a great difference in the coupling recovery time at different positions, and a bright block may appear between adjacent flexible printed circuit boards.

A region of the display region away from the flexible printed circuit board is a far end, and a region of the display region close to the flexible printed circuit board is a near end. A common signal feedback line configured for detecting the far-end common signal and the near-end common signal is provided at the periphery of the display region. When the common signal feedback line detects that the waveform of the far-end common signal fluctuates greatly, a common signal compensation point can be set through the corresponding common signal transmission line between adjacent flexible printed circuit boards to compensate the above-mentioned far-end common signal; when the far-end common signal is detected to be normal, a general common signal is input to the position of the common signal compensation point. For example, when the waveform of the far-end common signal is detected to be in an upward fluctuation relative to the voltage of the common signal equilibrium point, the compensation method adopts reverse complementation, and when the compensation signal acts on the waveform, the upward fluctuation can be pulled back to the equilibrium point.

Vcom recovery is extremely fast at the position with the compensation point between circuit boards, the recovery time thereof differs greatly from the coupling recovery time of Vcom at other positions, and a bright block occurs to the corresponding display region between circuit boards. In addition, under the same product size and the same number of circuit boards, the in-screen Vcom of a general display device with transverse common electrode lines is relatively small, but for large-sized products and few Vcom compensation points, the above display device with transverse common electrode lines is also prone to this defect.

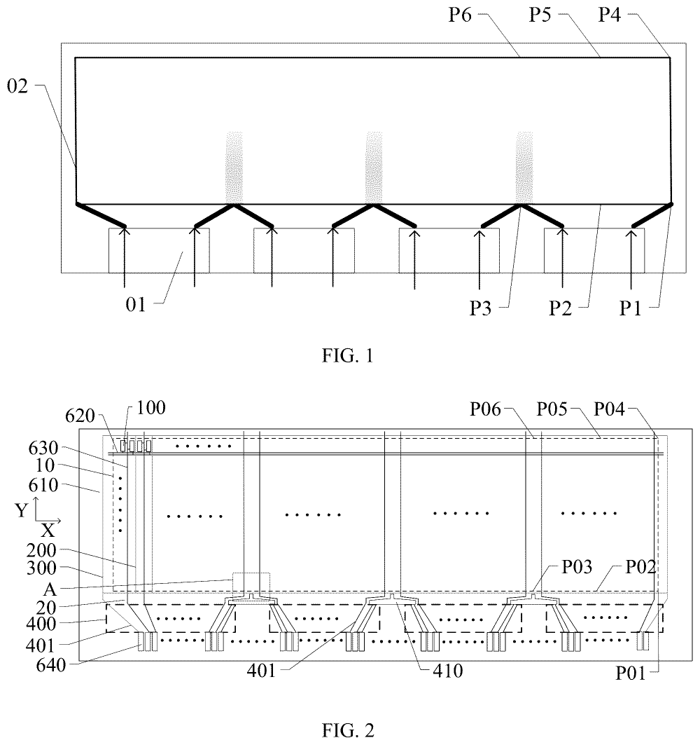

FIG. 1 is a partial structural view of a display device. As shown in FIG. 1, the display device includes a common signal transmission line 02 located in a non-display region and a plurality of circuit boards 01. Part of the edge region of each circuit board 01 is electrically connected with the common signal transmission line 02 in the display panel, the arrow shown in FIG. 1 represents the near-end compensation point of the circuit, the near-end compensation path of the common voltage enters the common signal transmission line 02 through the position between the circuit boards, and a bright block occurs to the corresponding display region between the circuit boards. Due to the coupling of data signals, the common voltage (Vcom) is no longer a fixed value, and it appears to rise and fall with the data signals.

As shown in FIG. 1, when the circuit board 01 compensates several positions of the common signal transmission line 02 close to the circuit board 01, such as position P3, it is found through testing the common voltage waveforms at one side of the display screen close to the circuit board and at the other side of the display screen away from the circuit board that: the common voltage waveforms at the positions of the display screen away from the circuit board 01, such as positions P4, P5 and P6, are basically the same, but the common voltage waveforms at the positions of the display screen close to the circuit board 01, such as positions P1, P2 and P3, are quite different. For example, the coupling amplitude at positions P1 and P2 is 760 mV, and the common voltage waveform recovery time is 6.5 us; the coupling amplitude at position P3 is 780 mV, and the common voltage waveform recovery time is 2.4 us; the coupling amplitude at positions P4 and P5 is 705 mV, and the common voltage waveform recovery time is 6.6 us; the coupling amplitude at position P6 is 760 mV, and the common voltage waveform recovery time is 6.6 us. It can be seen that the recovery time of the common voltage at the compensation point P3 between adjacent circuit boards 01 is quite different from the recovery time of the common voltage at the non-compensation point P2 between non-adjacent circuit boards 01; the recovery of the common voltage at position P3 is faster, and the charging influence is smaller, while the recovery of the common voltage at position P2 is slower, and it is not restored within the charging time, which affects the pixel charging and ultimately forms a bright block between adjacent circuit boards. In addition, the brightness of block formed in the region of the display screen close to the circuit board is greater than the brightness of block formed in the region of the display screen away from the circuit board.

The present disclosure provides an array substrate, a display panel and a display device.

An array substrate provided by an embodiment of the present disclosure includes a display region and a non-display region located on at least one side of the display region. The array substrate includes a plurality of sub-pixels, a plurality of common electrode lines, a common signal transmission line and a plurality of fanout wiring regions. At least part of the plurality of sub-pixels is located in the display region, and the sub-pixels located in the display region include a common electrode; the plurality of common electrode lines is located in the display region and electrically connected with the common electrode of the sub-pixels, and the plurality of common electrode lines is arranged along a first direction; the common signal transmission line is disposed in the non-display region and electrically connected with the plurality of common electrode lines; the plurality of fanout wiring regions is located in the non-display region, and the plurality of fanout wiring regions is arranged along the first direction. Among the plurality of fanout wiring regions, a wire located in the fanout wiring region at an edge in the first direction is electrically connected with the common signal transmission line, a conductive structure is disposed between at least one fanout wiring region and the common signal transmission line, the conductive structure is electrically connected with a wire located at an edge in the at least one fanout wiring region, and the conductive structure is separated from the common signal transmission line. By setting the conductive structure and the common signal transmission line separated from each other, it is helpful to reduce the difference in coupling recovery time of the common voltage at different positions of the array substrate, reduce the probability of display defect and improve the display effect.

Another embodiment of the present disclosure provides an array substrate, which includes a display region and a non-display region located on at least one side of the display region. The array substrate includes a plurality of sub-pixels, a plurality of common electrode lines, a common signal transmission line, a plurality of fanout wiring regions and a plurality of first connection structures. At least part of the plurality of sub-pixels is located in the display region, and the sub-pixels located in the display region include a common electrode; the plurality of common electrode lines is located in the display region and electrically connected with the common electrode of the sub-pixels, and the plurality of common electrode lines is arranged along a first direction; the common signal transmission line is disposed in the non-display region and electrically connected with the plurality of common electrode lines; the plurality of fanout wiring regions is located in the non-display region, and the plurality of fanout wiring regions is arranged along the first direction; the plurality of first connection structures is located between the common signal transmission line and the plurality of fanout wiring regions, and the plurality of first connection structures is arranged along the first direction. Wires in at least part of the plurality of fanout wiring regions are electrically connected with the common signal transmission line through the plurality of first connection structures; the number of the plurality of fanout wiring regions is N, the common signal transmission line includes a first transmission portion extending in the first direction and located between the display region and the plurality of fanout wiring regions, the length of the first transmission portion is L, and the resistance of the part, with the length of L/2N, of the first transmission portion is not greater than 30 ohms. By setting the parameters, such as the width and thickness, of the first transmission portion, so that the resistance of the part with the length of L/2N of the first transmission portion is not greater than 30 ohms, it is helpful to reduce the difference in coupling recovery time of the common voltage at different positions in the region of the array substrate close to the circuit board, reduce the coupling recovery time of the common voltage at different positions in the region of the array substrate close to the circuit board, reduce the probability of display defect and improve the display effect.

Another embodiment of the present disclosure provides an array substrate, which includes a display region and a non-display region located on at least one side of the display region. The array substrate includes a plurality of sub-pixels, a plurality of common electrode lines, a common signal transmission line, a fanout wiring region and a plurality of connection structures. At least part of the plurality of sub-pixels is located in the display region, and the sub-pixels located in the display region include a common electrode; the plurality of common electrode lines is located in the display region and electrically connected with the common electrode of the sub-pixels, and the plurality of common electrode lines is arranged along a first direction; the common signal transmission line is arranged in the non-display region and electrically connected with the plurality of common electrode lines; the fanout wiring region is located in the non-display region; the plurality of connection structures is located between the common signal transmission line and the plurality of fanout wiring regions, and the plurality of connection structures is arranged along the first direction. The fanout wiring region includes a middle region and edge regions located at both sides of the middle region in the first direction, and a wire in the middle region of the fanout wiring region is electrically connected with the common signal transmission line through at least one connection structure among the plurality of connection structures. By setting the connection structure connected with the middle region of the fanout wiring region, it is helpful to adjust the positions of the compensation points of the circuit board to the array substrate, e.g., increasing the number of compensation points of the circuit board to the array substrate, and it is helpful to reduce the difference of coupling recovery time of the common voltage at different positions in the region of the array substrate close to the circuit board, reduce the probability of display defect and improve the display effect.

The array substrate, the display panel and the display device provided by the embodiments of the present disclosure are described below with reference to the accompanying drawings.

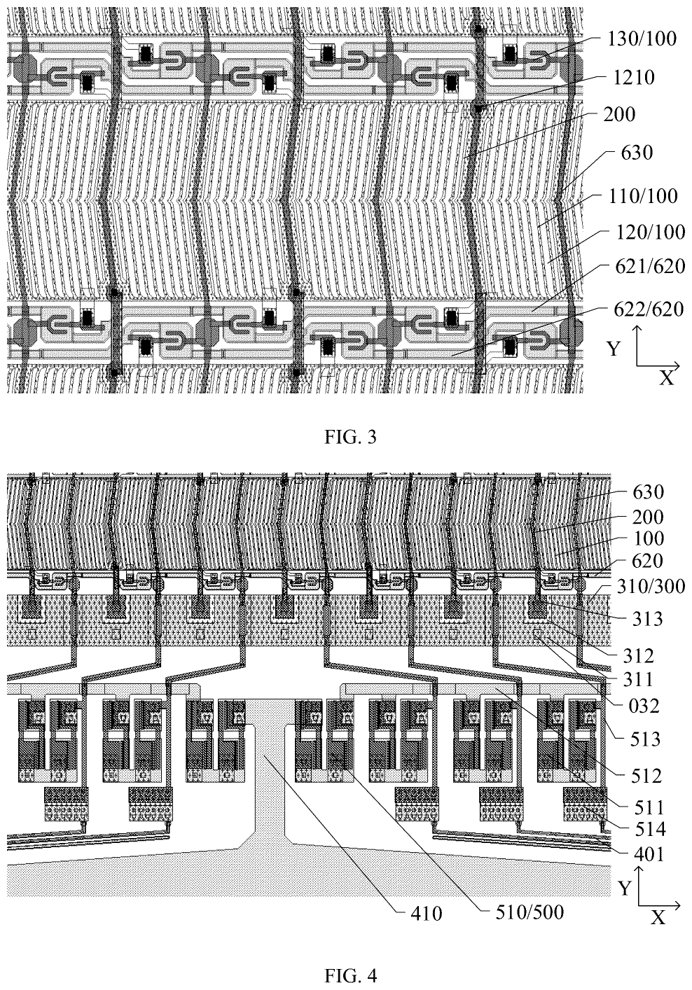

FIG. 2 is a partial structural view of an array substrate provided by an embodiment of the present disclosure, FIG. 3 is a partial structural view of the display region shown in FIG. 2, and FIG. 4 is an enlarged view of region A of the array substrate shown in FIG. 2.

As shown in FIGS. 2-4, the array substrate includes a display region 10 and a non-display region 20 located on at least one side of the display region 10. For example, the display region 10 is a region used for display; and the non-display region 20 surrounds the display region 10, and for example, the non-display region 20 is a region not used for display.

It should be noted that a dual-gate structure is illustrated in the present disclosure, thus reducing the number of data lines. Of course, it can also be a single-gate structure in the present disclosure, that is, the gate line in a same row corresponds to one sub-pixel row, and two adjacent sub-pixel columns are connected with different data lines. The specific display architecture is not limited in the present disclosure.

As shown in FIGS. 2-4, the array substrate includes a plurality of sub-pixels 100, and at least part of the plurality of sub-pixels 100 is located in the display region 10. For example, the sub-pixels 100 located in the display region 10 are arrayed along a first direction and a second direction. FIGS. 2-4 illustratively show that the first direction is the X direction and the second direction is the Y direction, but it is not limited thereto, and the first direction and the second direction can be interchanged.

As shown in FIGS. 2-4, the sub-pixels 100 located in the display region 10 include a common electrode 110. The array substrate includes a plurality of common electrode lines 200, the plurality of common electrode lines 200 is located in the display region 10 and electrically connected with the common electrodes 110 of the sub-pixels 100, and the plurality of common electrode lines 200 is arranged along the first direction. For example, the array substrate includes a base substrate 610, the common electrode 110 is located at one side of the common electrode lines 200 away from the base substrate 610, and the common electrode 110 is electrically connected with the common electrode lines 200 through vias 1210 in an insulating layer between the common electrode 110 and the common electrode lines 200. For example, the common electrode 110 of one row of sub-pixels 100 arranged along the first direction can be an integrated structure. For example, the via 1210 can be a semi-via; for example, the shape of the orthographic projection of the semi-via on the base substrate is an unclosed ring, which is helpful to improve the uniformity of the alignment film formed at one side of the common electrode away from the base substrate.

The array substrate includes a common signal transmission line 300 disposed in the non-display region 20, and the common signal transmission line 300 is electrically connected with the plurality of common electrode lines 200. For example, the common signal transmission line 300 surrounds the display region 10. For example, the boundary of the display region shown in FIG. 4 can be a gap between the sub-pixels 100 and the common signal transmission line 300, or an edge of the sub-pixels 100 close to the common signal transmission line 300. For example, one row of sub-pixels 100 closest to the common signal transmission line 300 shown in FIG. 4 can be sub-pixels used for display or dummy sub-pixels not used for display.

The array substrate provided by the present disclosure is only provided with a plurality of common electrode lines arranged along the first direction, and for example, only the vertically extending common electrode lines are provided, and the horizontally extending common electrode lines are not provided, which is helpful to save space and improve the transmittance of the array substrate at the same time.

As shown in FIGS. 2-4, the array substrate includes a plurality of fanout wiring regions 400 located in the non-display region 20, and the plurality of fanout wiring regions 400 is arranged along the first direction. For example, the plurality of fanout wiring regions 400 is located at one side of the display region 10 in the second direction. For example, FIG. 2 illustratively shows four fanout wiring regions 400, but it is not limited thereto, and the number of fanout wiring regions can be set according to product requirements and product size. For example, each fanout wiring region 400 includes a plurality of wires 401.

As shown in FIGS. 2-4, among the plurality of fanout wiring regions 400, a wire 401 located in the fanout wiring region 400 at an edge in the first direction is electrically connected with the common signal transmission line 300. For example, the edge here can be an outermost position or a position close to an edge in the fanout wiring region, which is not limited here, and the outermost position is illustratively shown in the drawings. For example, the wires 401 of two fanout wiring regions 400 located at both edges among the plurality of fanout wiring regions 400 are electrically connected with the common signal transmission line 300.

As shown in FIGS. 2-4, a conductive structure 410 is disposed between at least one fanout wiring region 400 and the common signal transmission line 300, the conductive structure 410 is electrically connected with a plurality of wires 401 located at an edge in at least one fanout wiring region 400, and the conductive structure 410 is separated from the common signal transmission line 300. It should be noted that “the conductive structure 410 being separated from the common signal transmission line 300” here means that there is a gap between the conductive structure 410 and the common signal transmission line 300, and the conductive structure and the common signal transmission line are not directly connected, e.g., are coupled; in the case where the film layer included in the conductive structure and the film layer included in the common signal transmission line have structures in a same layer, there is a gap between the structures in the same layer, and they are not integrally formed or directly connected together. Optionally, the conductive structure and the common signal transmission line are coupled, that is, they are electrically connected through an electrostatic discharge structure (when the electrostatic discharge structure works) so as to transmit a same signal. Optionally, the same signal is a common signal. For example, at least one film layer of the common signal transmission line 300 and the conductive structure 410 are arranged in the same layer and made of the same material.

For example, as shown in FIG. 2, the array substrate further includes a bonding structure 640 located at one side of the fanout wiring region 400 away from the display region 10. For example, the bonding structure 640 includes a plurality of pads used for bonding the circuit board. For example, the wire in one fanout wiring region 400 is electrically connected with one circuit board (first circuit board described later) through the bonding structure 640. For example, the plurality of fanout wiring regions 400 is electrically connected with a plurality of circuit boards in one-to-one correspondence. For example, the circuit board is electrically connected with the common signal transmission line 300 through the wire in the fanout wiring region 400. For example, the conductive structure 410 is electrically connected with the circuit board through the wire in the fanout wiring region 400. For example, the fanout wiring region 400 can be a region, where the fanout wire 401 is located, between the bonding structure 640 and the display region 10.

For example, as shown in FIG. 2, the number of conductive structures 410 is plural, each fanout wiring region 400 includes a wire 401 electrically connected with the conductive structure 410, and the plurality of conductive structures 410 is separated from the common signal transmission line 300.

For example, as shown in FIG. 2, during testing the common voltage waveform of the array substrate, the conductive structure 410 and the common signal transmission line 300 are separated from each other, e.g., disconnected from each other, so that the coupling recovery time of the common voltage at the positions of the display region 10 away from the fanout wiring region 400, such as positions P04, P05 and P06, can have little difference from the coupling recovery time of the common voltage at the positions of the display region 10 close to the fanout wiring region 400, such as positions P01, P02 and P03. For example, the coupling amplitude at position P01 is 770 mV, the common voltage waveform recovery time is 7.0 us; the coupling amplitude at position P02 is 795 mV, the common voltage waveform recovery time is 7.2 us; the coupling amplitude at position P03 is 797 mV, the common voltage waveform recovery time is 7.0 us; the coupling amplitude at position P04 is 757 mV, the common voltage waveform recovery time is 7.4 us; the coupling amplitude at position P05 is 722 mV, the common voltage waveform recovery time is 7.4 us; the coupling amplitude at position P06 is 750 mV, and the common voltage waveform recovery time is 7.4 us. That is, the difference in the common voltage waveform recovery time at different positions is within 1 us.

In the array substrate provided by the embodiment of the present disclosure, the common signal transmission line and the conductive structure electrically connected with the wire in the fanout wiring region are separated from each other, which is helpful to reduce the difference in coupling recovery time of the common voltage at different positions close to the circuit board in the display region and prevent bright block from appearing in the display region between adjacent fanout wiring regions, and is helpful to alleviate defects and improve the display effect.

In some examples, as shown in FIGS. 2-4, the number of conductive structures 410 is plural, the plurality of conductive structures 410 is arranged along the first direction, and at least one conductive structure 410 is electrically connected with two parts of the wires 401, close to each other, in two adjacent fanout wiring regions 400. For example, at least part of the conductive structure 410 is located between adjacent fanout wiring regions 400. For example, two parts of wires located at both edges of the same fanout wiring region 400 are electrically connected with different conductive structures 410, respectively, and two parts of wires 401 located at two edges, close to each other, of two adjacent fanout wiring regions 400 are electrically connected with the same conductive structure 410.

In some examples, as shown in FIGS. 2-4, the array substrate further includes a base substrate 610, a plurality of gate lines 620 and a plurality of data lines 630 located on the base substrate 610. The plurality of gate lines 620 is arranged along the second direction, and the second direction intersects with the first direction. For example, the first direction is perpendicular to the second direction. Of course, the embodiment of the present disclosure is not limited thereto, and the included angle between the first direction and the second direction can be in the range of 80-100 degrees. For example, the plurality of data lines 630 is arranged along the first direction, the plurality of data lines 630 is located at one side of the plurality of gate lines 620 away from the base substrate 610, and the common electrode 110 is located at one side of the plurality of data lines 630 away from the base substrate 610. For example, at least part of the wires 401 in the fanout wiring region 400 are arranged in the same layer as the gate lines 620.

For example, as shown in FIG. 3, the data line 630 can be provided with a widened portion, which is, for example, located between adjacent sub-pixels; and the widened portion can be used to provide a spacer (PS) thereon.

For example, as shown in FIGS. 2-4, the sub-pixel 100 located in the display region 10 further includes a switching structure 130 and a pixel electrode 120. For example, the pixel electrode 120 can be a block structure, and the common electrode 110 can be a slit structure. For example, the common electrode 110 can include a plurality of strip structures. The common electrode is disposed at one side of the pixel electrode away from the base substrate. It should be noted that it can also be the pixel electrode which is disposed at one side of the common electrode away from the base substrate in the present disclosure; in this case, the common electrode can be a block structure, and the pixel electrode is provided with a plurality of slits.

For example, as shown in FIGS. 2-4, the switching structure 130 includes three electrodes electrically connected with the gate line 620, the data line 630 and the pixel electrode 120, respectively. For example, the switching structure 130 can be a thin film transistor, the gate electrode of the thin film transistor is electrically connected with the gate line 620, one of the source electrode and the drain electrode of the thin film transistor is electrically connected with the data line 630, and the other of the source electrode and the drain electrode of the thin film transistor is electrically connected with the pixel electrode 120. In the present disclosure, the transistor can include amorphous silicon, oxide or low-temperature polysilicon, which is not limited here. In addition, the transistor can be a bottom gate structure (the gate electrode is disposed between the semiconductor layer and the base substrate), or can be a top gate structure (the gate electrode is disposed at one side of the semiconductor layer away from the base substrate), which is not limited here.

In some examples, as shown in FIGS. 2-4, the plurality of sub-pixels 100 is arrayed along the first direction and the second direction, two sub-pixel columns arranged along the first direction are disposed between adjacent data lines 630, the sub-pixels 100 in each sub-pixel column are arranged along the second direction, different sub-pixels 100 connected with a same data line 630 are connected with different gate lines 620, the plurality of gate lines 620 includes first gate lines 621 and second gate lines 622 alternately arranged along the second direction, and a gate line pair formed by the first gate line 621 and the second gate line 622 is disposed between two adjacent sub-pixels 100 arranged along the second direction. In the array substrate provided by the present disclosure, two gate lines are disposed between adjacent pixel rows, and a horizontally arranged common electrode line is omitted between the two gate lines, which is helpful to save metal wiring and space, and improve the light transmittance of the array substrate at the same time.

In some examples, as shown in FIGS. 2-4, the plurality of data lines 630 and the plurality of common electrode lines 120 are alternately arranged along the first direction. For example, the data line 630 is electrically connected with the bonding structure 640 through the wire 401 in the fanout wiring region 400 so as to be electrically connected with the circuit board, and the common electrode line 200 is electrically connected with the common signal transmission line 300.

In some examples, as shown in FIG. 4, the array substrate further includes an electrostatic discharge structure 500, which is located in the non-display region 20 and between the common signal transmission line 300 and the plurality of fanout wiring regions 400. For example, the fanout wiring region 400 is located between the electrostatic discharge structure 500 and the bonding structure 640.

In some examples, as shown in FIG. 4, the conductive structure 410 is electrically connected with the electrostatic discharge structure 500.

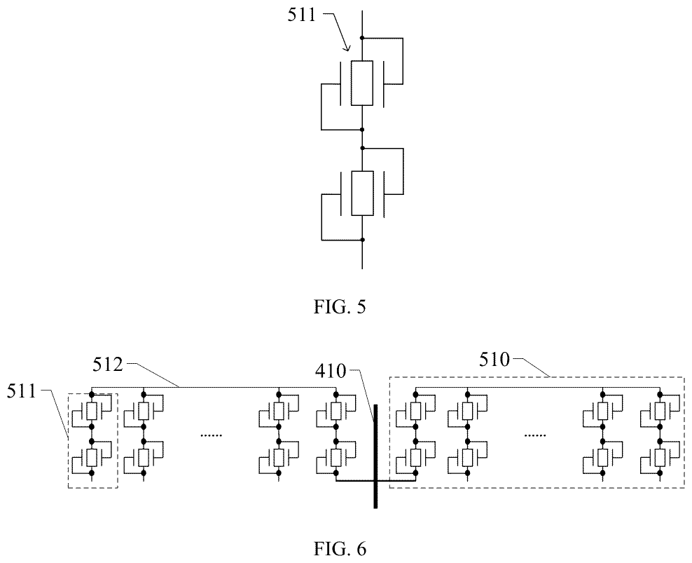

FIG. 5 is a circuit diagram of an electrostatic discharge unit of the electrostatic discharge structure shown in FIG. 4, and FIG. 6 is a circuit diagram of two electrostatic discharge unit groups shown in FIG. 4.

For example, as shown in FIGS. 4-6, the electrostatic discharge structure 500 includes a plurality of electrostatic discharge unit groups 510. For example, one conductive structure 410 can pass through the gap between adjacent electrostatic discharge unit groups 510 and be electrically connected with the adjacent electrostatic discharge unit groups 510.

In some examples, as shown in FIGS. 2-6, each electrostatic discharge unit group 510 includes a plurality of electrostatic discharge units 511 and a connection wire 512 connecting the plurality of electrostatic discharge units 511, one end of at least part of the plurality of electrostatic discharge units 511 is electrically connected with the connection wire 512, and the other end of the at least part of the plurality of electrostatic discharge units 511 is electrically connected with the plurality of data lines 630.

For example, as shown in FIG. 4, the data line 630 is electrically connected with the electrostatic discharge unit 511 through a data line connection line 513, and the data line connection line 513 and the data line 630 can be structures disposed in the same layer. For example, the data line connection line 513 and the data line 630 can be an integrated structure. For example, the data line connection line 513 is electrically connected with the wire 401 in the fanout wiring region through a transfer portion 514, and the transfer portion here is configured to transfer the data line disposed in a source-drain metal layer to a gate line layer. Optionally, a hole can be dug in the insulating layer located at one side of the insulating layer located at one side of the transfer portion away from the base substrate, and an electrode layer (e.g., in the same layer as the pixel electrode or common electrode) can be electrically connected with the film layer where the data line is located and the film layer where the gate line is located by digging holes.

For example, as shown in FIG. 5, each electrostatic discharge unit 511 includes a plurality of transistors which is electrically connected; one end of the electrostatic discharge unit 511 is electrically connected with the connection wire 512, for example, the connection wire 512 can be an electrostatic discharge ring; and the other end of the electrostatic discharge unit 511 is electrically connected with the data line or the conductive structure 410. For example, two electrostatic discharge units 511 located at both edges of at least one electrostatic discharge unit group 510 are electrically connected with the conductive structure 410, and the electrostatic discharge units 511 located at non-edge positions in the at least one electrostatic discharge unit group 510 are electrically connected with the data lines 630. Of course, the embodiment of the present disclosure is not limited thereto, and one of the two electrostatic discharge units located at both edges of the electrostatic discharge unit group can be electrically connected with the conductive structure, while the other of the two electrostatic discharge units located at both edges of the electrostatic discharge unit group can be electrically connected with the data line.

FIGS. 5 and 6 illustratively show that one electrostatic discharge unit includes four thin film transistors, but it is not limited thereto, and one electrostatic discharge unit can also include two, three, five, six, seven, eight, nine or more thin film transistors.

For example, as shown in FIGS. 2-6, each fanout wiring region 400 corresponds to one electrostatic discharge unit group 510, the plurality of wires 401 electrically connected with the data lines 630 in each fanout wiring region 400 are electrically connected with a same electrostatic discharge unit group 510, and the plurality of wires 401 electrically connected with the data lines 630 in different fanout wiring regions 400 are electrically connected with different electrostatic discharge unit groups 510.

For example, as shown in FIG. 4, the connection line 512 and the conductive structure 410 are structures disposed in the same layer. For example, the connection line 512 and the gate line 620 are structures disposed in the same layer.

For example, as shown in FIG. 4, the connection wire 512 is located in a region between the conductive structure 410 and the common signal transmission line 300. For example, the edge of the electrostatic discharge unit 511 close to the common signal transmission line 300 can be flush with the edge of the conductive structure 410 close to the common signal transmission line 300.

For example, as shown in FIG. 4, the part of the conductive structure 410 close to the display region can be a block structure, and the block-shaped conductive structure can reduce the impedance of signal transmission.

In the array substrate provided by the present disclosure, the conductive structure configured to be electrically connected with the bonding structure is separated from the common signal transmission line, and at the same time, the conductive structure is electrically connected with the electrostatic discharge structure, so that the electrostatic risk can be reduced and the display uniformity can be improved.

In some examples, as shown in FIGS. 2-4, the common signal transmission line 300 includes a first transmission portion 310 extending in the first direction and located between the display region 10 and the plurality of fanout wiring regions 400, the first transmission portion 310 includes a first conductive layer 311 and a second conductive layer 312 which are stacked, the first conductive layer 311 is located between the second conductive layer 312 and the base substrate 610, the first conductive layer 311 is disposed in the same layer as the gate line 620, and the second conductive layer 312 is disposed in the same layer as the common electrode 110.

In some examples, as shown in FIG. 4, the first conductive layer 311 includes a plurality of notches, the plurality of common electrode lines 200 is electrically connected with the first transmission portion 310 through a plurality of connection blocks 313, and the plurality of connection blocks 313 is disposed in the same layer as the plurality of data lines 630, and the plurality of notches of the first conductive layer 311 is configured to expose the plurality of connection blocks 313.

In some examples, as shown in FIG. 4, in the direction perpendicular to the base substrate, e.g., the direction perpendicular to the XY plane, the plurality of connection blocks 313 does not overlap with the first conductive layer 311, the plurality of connection blocks 313 overlaps with the second conductive layer 312, and the plurality of connection blocks 313 is electrically connected with the first conductive layer 311 through the second conductive layer 312. For example, the insulating layer between the first conductive layer 311 and the second conductive layer 312 includes a via 032 which is located at one side of the connection block 313 away from the display region, and the first conductive layer 311 and the second conductive layer 312 are electrically connected through the via 032. For example, a straight line extending in the second direction passes through the orthographic projections of the connection block 313 and the above-mentioned via on the base substrate. For example, the specific number of vias 032 is not limited, and one via is shown in the figure.

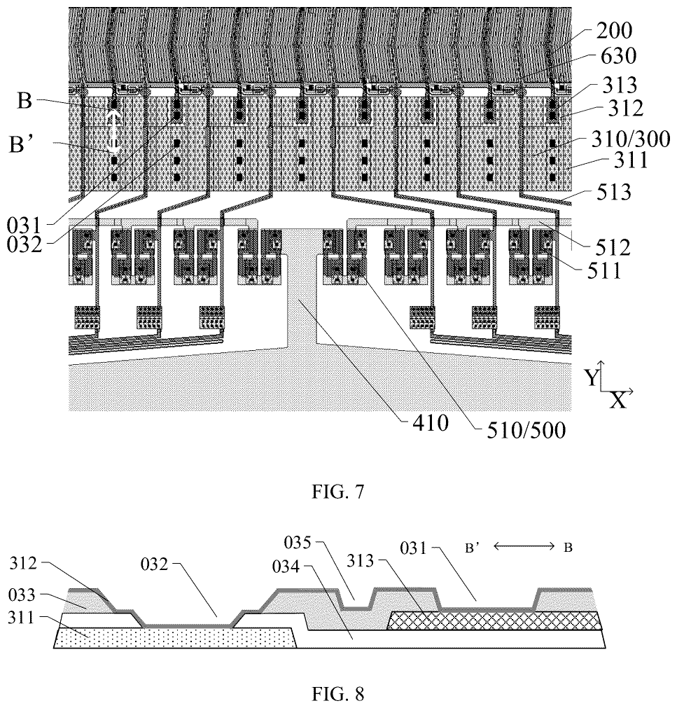

FIG. 7 is an enlarged view of region A of the array substrate shown in FIG. 2 in another example. The array substrate shown in FIG. 7 is different from the array substrate shown in FIG. 4 in that the width of the common signal transmission line 300 between the display region and the conductive structure 410 is different.

In some examples, as shown in FIGS. 2 and 7, the number of the plurality of fanout wiring regions 400 is N, the length of the first transmission portion 310 is L, the resistance of the part, with the length of L/2N, of the first transmission portion 310 is not greater than 30 ohms, where N is a positive integer. For example, the first transmission portion 310 is a portion of the common signal transmission line 300 extending in the first direction and located between the display region 10 and the fanout wiring region 300. For example, the resistance of the part of the first transmission portion 310 with the length of L/2N is not greater than 29 ohms. For example, the resistance of the part of the first transmission portion 310 with the length of L/2N is not greater than 28 ohms. For example, the resistance of the part of the first transmission portion 310 with the length of L/2N is not greater than 27 ohms. For example, the resistance of the part of the first transmission portion 310 with the length of L/2N is not greater than 26 ohms. For example, the resistance of the part of the first transmission portion 310 with the length of L/2N is not greater than 25 ohms. For example, the resistance of the part of the first transmission portion 310 with the length of L/2N is not greater than 24 ohms. For example, the resistance of the part of the first transmission portion 310 with the length of L/2N is not greater than 23 ohms. For example, the resistance of the part of the first transmission portion 310 with the length of L/2N is not greater than 22 ohms. For example, the resistance of the part of the first transmission portion 310 with the length of L/2N is not greater than 21 ohms. For example, the resistance of the part of the first transmission portion 310 with the length of L/2N is not greater than 20 ohms. For example, the resistance of the part of the first transmission portion 310 with the length of L/2N is not greater than 19 ohms. For example, the resistance of the part of the first transmission portion 310 with the length of L/2N is not greater than 18 ohms. For example, the resistance of the part of the first transmission portion 310 with the length of L/2N is not greater than 17 ohms. For example, the resistance of the part of the first transmission portion 310 with the length of L/2N is not greater than 16 ohms. For example, the resistance of the part of the first transmission portion 310 with the length of L/2N is not greater than 15 ohms. For example, the resistance of the part of the first transmission portion 310 with the length of L/2N is not greater than 14 ohms. For example, the resistance of the part of the first transmission portion 310 with the length of L/2N is not greater than 13 ohms. For example, the resistance of the part of the first transmission portion 310 with the length of L/2N is not greater than 12 ohms. For example, the resistance of the part of the first transmission portion 310 with the length of L/2N is not greater than 11 ohms. For example, the resistance of the part of the first transmission portion 310 with the length of L/2N is not greater than 10 ohms.

For example, as shown in FIGS. 2 and 7, the length of the first transmission portion 310 is L, the width of the first transmission portion 310 can be W, and Rₛ is the square resistance of the first transmission portion 310, so the resistance of the part of the first transmission portion 310 with the length of L/2N is R=L×Rₛ/(2N×W). The above Rₛ is related to the thickness of the first transmission portion 310, e.g., the thickness of the first conductive layer 311 and the thickness of the second conductive layer 312. The greater the thickness of the first transmission portion 310, the smaller the Rₛ. For example, the width of the first transmission portion 310 can be in the range of 200-300 microns. For example, the width of the first transmission portion 310 can be in the range of 220-280 microns. For example, the width of the first transmission portion 310 can be in the range of 250-275 microns. For example, N can be in the range of 2-20. For example, N can be in the range of 10-18. For example, N can be in the range of 12-16. For example, N can be in the range of 3-6. For example, N can be in the range of 5-7. For example, N can be 4. For example, the ratio of the length L of the first transmission portion 310 to the length of the display region is in the range of 0.8-1.2. For example, the ratio of the length L of the first transmission portion 310 to the length of the display region is in the range of 0.9-1.1. For example, the range of Rₛ is 0.04-0.1.

As can be seen from the formula of the resistance of the first transmission portion, the greater the width and thickness of the part of the first transmission portion with the length of L/2N or the larger the number of fanout wiring regions, the smaller the resistance of the part of the first transmission portion with the length of L/2N.

In the array substrate provided by the present disclosure, by setting the width and thickness of the first transmission portion, it is helpful to adjust the resistance of the first transmission portion, so as to improve the ability of the common signal transmission line to transmit electric signals and improve the display uniformity of the display panel.

For example, compared with the width of the first transmission portion 310 shown in FIG. 4, the width of the first transmission portion 310 shown in FIG. 7 is increased, so that the number of vias in the insulating layer between the connection block 313 and the second conductive layer 312 can be increased; and further, the number of vias in the insulating layer between the first conductive layer 311 and the second conductive layer 312 can also be increased, which is helpful to further reduce the resistance of the common signal transmission line 300.

FIG. 8 is a partial cross-sectional structural view taken along line BB′ shown in FIG. 7. For example, as shown in FIGS. 7 and 8, in the direction perpendicular to the substrate, e.g., the direction perpendicular to the XY plane, the connection block 313 does not overlap with the first conductive layer 311, the first conductive layer 311 is located at one side of the second conductive layer 312 facing the base substrate, insulating layers 033 and 034 are disposed between the first conductive layer 311 and the second conductive layer 312, the connection block 313 is located on the insulating layer 034, the insulating layer 033 is located between the connection block 313 and the second conductive layer 312, the connection block 313 is electrically connected with the second conductive layer 312 through the via 031 in the insulating layer 033, and the second conductive layer 312 is electrically connected with the first conductive layer 311 through the via 032 in the insulating layers 033 and 034, so as to realize the electrical connection between the connection block 313 and the first conductive layer 311.

For example, as shown in FIG. 8, the insulating layer 033 located at the gap between the connection block 313 and the first conductive layer 311 has a groove 035. For example, if the depth of the groove 035 is relatively deep, it is easy to cause the second conductive layer 312 to be disconnected at the position of the groove 035 and increase the resistance of the common signal transmission line 300.

For example, as shown in FIG. 7, a plurality of vias 031 and a plurality of vias 032 (the vias 032 are configured to realize the electrical connection between the first conductive layer 311 and the second conductive layer 312, and the number of vias is not limited) are disposed between adjacent data line connection lines 513; and between adjacent data line connection lines 513, the plurality of vias 031 is arranged along the second direction, the plurality of vias 032 is arranged along the second direction, and the plurality of vias 031 and the plurality of vias 032 are arranged in one column along the second direction.

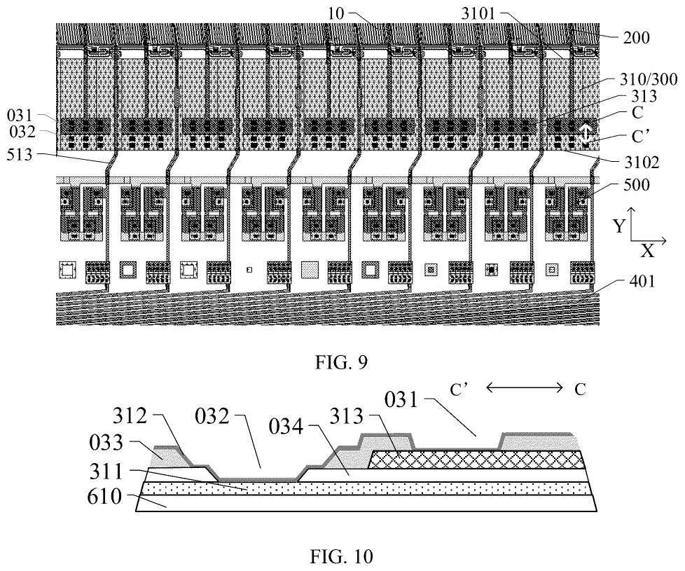

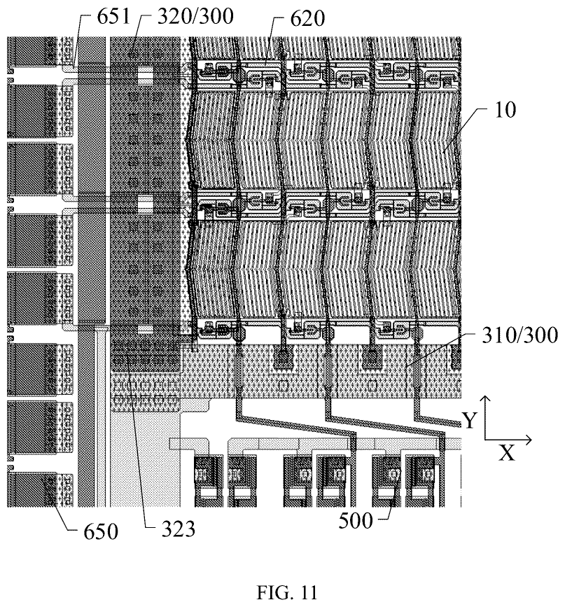

FIG. 9 is a partial planar structural view of the array substrate shown in FIG. 2 in another example, and FIG. 10 is a partial cross-sectional structural view taken along line CC′ shown in FIG. 9. The array substrate shown in FIG. 9 is different from the array substrate shown in FIG. 7 in that the positional relationship between the connection block and the first conductive layer is different and the position of the via electrically connecting the connection block and the common transmission signal line is different.

In some examples, as shown in FIGS. 9 and 10, the plurality of common electrode lines 200 is electrically connected with the first transmission portion 310 through a plurality of connection blocks 313, the orthographic projection of the plurality of connection blocks 313 on the base substrate 610 falls within the orthographic projection of the first conductive layer 311 on the base substrate 610, the orthographic projection of the plurality of connection blocks 313 on the base substrate falls within the orthographic projection of the second conductive layer 312 on the base substrate, and the plurality of connection blocks 313 is electrically connected with the first conductive layer 311 through the second conductive layer 312.

For example, as shown in FIGS. 9 and 10, insulating layers 033 and 034 are disposed between the first conductive layer 311 and the second conductive layer 312, the connection block 313 is located on the insulating layer 034, the insulating layer 033 is located between the connection block 313 and the second conductive layer 312, the connection block 313 is electrically connected with the second conductive layer 312 through the via 031 in the insulating layer 033, and the second conductive layer 312 is electrically connected with the first conductive layer 311 through the via 032 in the insulating layers 033 and 034, so as to realize the electrical connection between the connection block 313 and the first conductive layer 311.

By setting the connection block stacked with the first conductive layer, it can avoid the occurrence of groove, which may results in defects, such as the second conductive layer being disconnected, etc., and may further increase the resistance of the common signal transmission line, in the insulating layer at the gap between the connection block and the first conductive layer in the direction parallel to the base substrate.

In some examples, as shown in FIGS. 9 and 10, the first transmission portion 310 includes a first edge 3101 and a second edge 3102 extending in the first direction, the first edge 3101 is located at one side of the second edge 3102 close to the display region 10, and the distance between the connection block 313 and the second edge 3102 is less than the distance between the connection block 313 and the first edge 3101. The figure illustratively shows that the first edge and the second edge are straight lines extending in the first direction, but it is not limited thereto; at least one of the first edge and the second edge can be a fold line, and the overall extending direction of the fold line is the first direction.

For example, as shown in FIG. 9, the distance between the via 031 and the second edge 3102 is less than the distance between the via 031 and the first edge 3101, and the distance between the via 032 and the second edge 3102 is less than the distance between the via 032 and the first edge 3101.

In the array substrate provided by the present disclosure, by setting the connection block to be far away from the display region, it is helpful to set the via to be far away from the display region and to improve the flatness of the periphery of the display region, thus reducing Mura resulted from PI diffusion defects.

For example, as shown in FIG. 9, the number of vias 031 corresponding to the same connection block 313 is plural, and the plurality of vias 031 can be arrayed along the first direction and the second direction. For example, the number of vias 032 corresponding to the same connection block 313 is plural, and the plurality of vias 032 can be arrayed along the first direction and the second direction. For example, the plurality of vias 031 and the plurality of vias 032 are disposed between adjacent data line connection lines 513, and between adjacent data line connection lines 513, the plurality of vias 031 is arranged in an array and the plurality of vias 032 is arranged in an array.

In the array substrate provided by the present disclosure, by increasing the number of vias, it is helpful to further reduce the resistance of the common signal transmission line and to reduce the coupling recovery time and the difference in the coupling recovery time of the common voltage at different positions in the display region close to the fanout wiring region, thus improving the defects.

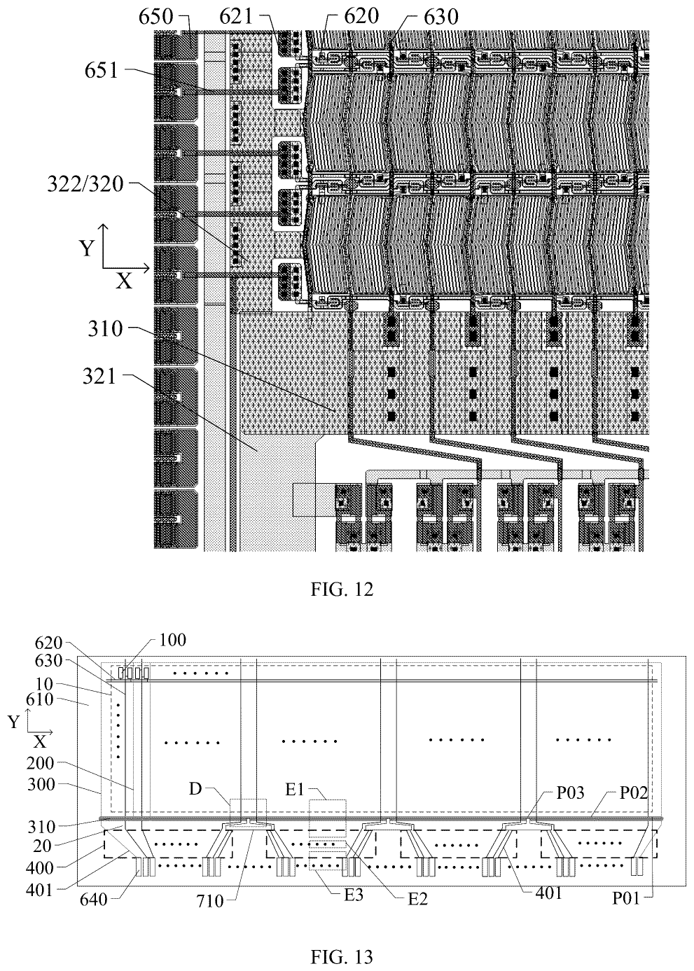

FIGS. 11 and 12 are partial planar structural views of the array substrate shown in FIG. 2 in different examples. FIGS. 11 and 12 illustratively show the common signal transmission line 300 at the intersection of the edge of the display region 10 close to the electrostatic discharge structure 500 and the edge of the display region 10 close to the gate driving structure 650. For example, as shown in FIGS. 11 and 12, the array substrate further includes a gate driving structure 650. Optionally, the gate driving structure can be a GOA gate driving circuit, and the gate driving structure 650 is electrically connected with the gate line 620 through a gate driving connection line 651. The connection mode between the first transmission portion 310 and the connection block 313 shown in FIG. 12 can be replaced by the connection mode between the first transmission portion 310 and the connection block 313 shown in FIG. 9. The first transmission portion 310 shown in FIG. 11 can be replaced by the first transmission portion 310 shown in FIG. 7 or FIG. 9.

For example, as shown in FIG. 11, the gate driving connection line 651 and the gate line 620 can be structures disposed in the same layer, the common signal transmission line 300 includes a second transmission portion 320 extending in the second direction, the second transmission portion 320 includes a film layer disposed in the same layer as the data line and a film layer disposed in the same layer as the common electrode, the gate driving connection line 651 overlaps with the second transmission portion 320 in the direction perpendicular to the base substrate, and for example, the gate driving connection line 651 passes through the second transmission portion 320 and is electrically connected with the gate line 620. For example, the second transmission portion 320 is electrically connected with the first transmission portion 310 through a transfer via 323, and herein, the second conductive layer realizes the electrical connection between the second transmission portion and the first transmission portion through the transfer via.

For example, as shown in FIG. 12, the gate driving connection line 651 and the data line 630 can be structures disposed in the same layer, the common signal transmission line 300 further includes a second transmission portion 320 extending in the second direction, the second transmission portion 320 includes a third conductive layer 321 and a fourth conductive layer 322 which are stacked, the third conductive layer 321 and the first conductive layer 311 are an integrated film layer, and the fourth conductive layer 322 and the second conductive layer 312 are an integrated film layer. For example, the first transmission portion 310 and the second transmission portion 320 can be an integrated structure.

For example, as shown in FIG. 12, the gate driving connection line 651 overlaps with the second transmission portion 320 in the direction perpendicular to the base substrate, and the gate driving connection line 651 passes through the second transmission portion 320 and is electrically connected with the gate line 620 through a transfer structure 621.

In the array substrate provided by the present disclosure, by setting the second transmission portion in the common signal transmission line into a structure integrated with the first transmission portion, it is helpful to omit the transfer via electrically connecting the first transmission portion and the second transmission portion, and further reduce the resistance of the common signal transmission line.

For example, the connection mode between the second transmission portion and the first transmission portion, and the connection mode between the gate driving structure and the gate line shown in FIGS. 11 and 12 can be applied to the array substrate shown in FIG. 4, FIG. 7 or FIG. 9.

For example, in the case where the second transmission portion and the gate driving structure shown in FIG. 12 are applied to the array substrate shown in FIG. 9, the size of the transfer structure 621 shown in FIG. 12 can be equivalent to the size of the connection block 313 shown in FIG. 9, and the arrangement of the vias corresponding to the transfer structure 621 is similar to the arrangement of the vias corresponding to the connection block 313, which is helpful to improve etching uniformity and reduce support-related defects. For example, the transfer structure and the gate driving structure include dual-layer metals, e.g., the metal of the layer where the gate line is located and the metal of the layer where the data line is located. By setting the connection block as an overlapping design of the first conductive layer and the second conductive layer, it is helpful to reduce the mismatch at different positions of the array substrate.

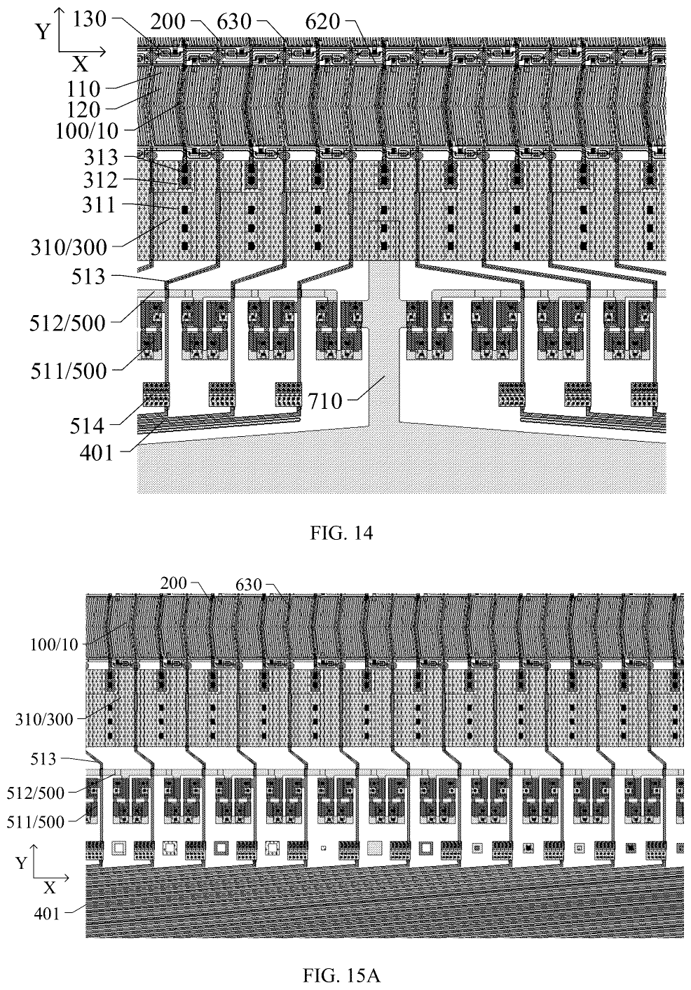

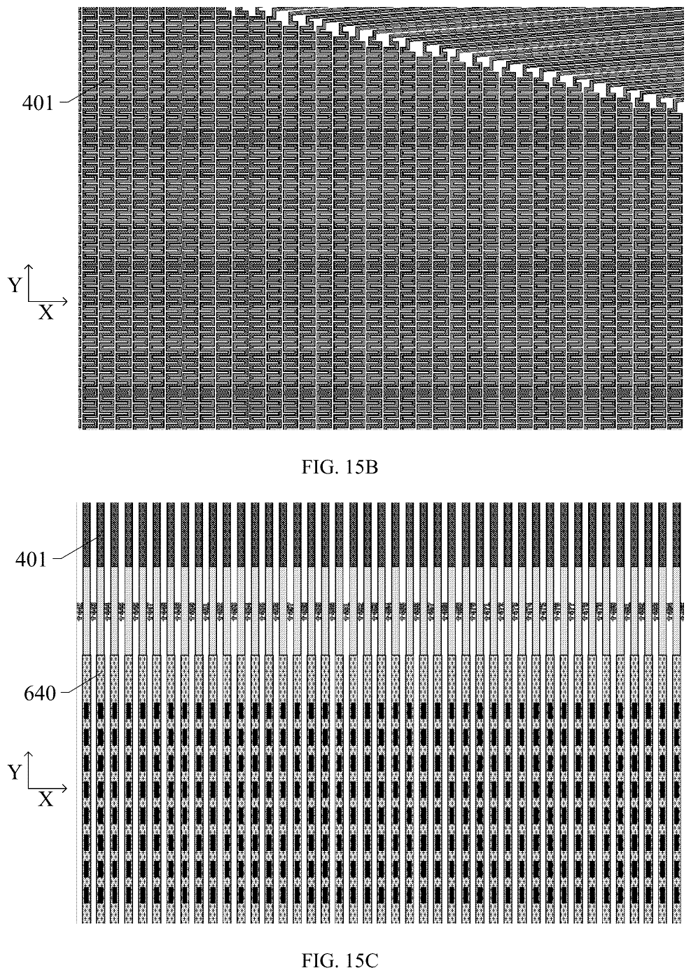

FIG. 13 is a partial planar structural view of an array substrate provided by another embodiment of the present disclosure; FIG. 14 is a partial structural view of region D shown in FIG. 13; FIG. 15A is a partial structural view of region E1 shown in FIG. 13; FIG. 15B is a partial structural view of region E2 shown in FIG. 13; and FIG. 15C is a partial structural view of region E3 shown in FIG. 13. As shown in FIGS. 13-15C, the array substrate includes a display region 10 and a non-display region 20 located on at least one side of the display region 10. The display region 10 shown in FIG. 13 can have the same features as the display region 10 shown in FIG. 2, and details will not be repeated here.

As shown in FIGS. 13-15C, the array substrate includes a plurality of sub-pixels 100, at least part of the plurality of sub-pixels 100 is located in the display region 10, and the sub-pixels 100 located in the display region 10 include a common electrode 110. For example, the sub-pixel 100 further includes a pixel electrode 120 and a switching structure 130. The sub-pixels in the array substrate provided by the present embodiment have the same features as the sub-pixels in the array substrate shown in FIG. 2, and details will not be repeated here.

As shown in FIGS. 13-15C, the array substrate includes a plurality of common electrode lines 200, a common signal transmission line 300 and a plurality of fanout wiring regions 400. The plurality of common electrode lines 200 is located in the display region 10 and electrically connected with the common electrode 110 of the sub-pixels 100, and the plurality of common electrode lines 200 is arranged along the first direction. The common signal transmission line 300 is disposed in the non-display region 20 and electrically connected with the plurality of common electrode lines 200; the plurality of fanout wiring regions 400 is located in the non-display region 20, and the plurality of fanout wiring regions 400 is arranged along the first direction.

The common electrode lines in the array substrate provided by the present embodiment have the same features as the common electrode lines in the array substrate shown in FIG. 2, and details will not be repeated here.

For example, the plurality of fanout wiring regions 400 is located at one side of the display region 10 in the second direction. For example, FIG. 13 illustratively shows four fanout wiring regions 400, but it is not limited thereto, and the number of fanout wiring regions can be set according to product requirements and product size. For example, each fanout wiring region 400 includes a plurality of wires 401.

As shown in FIGS. 13-15C, among the plurality of fanout wiring regions 400, a wire 401 located in the fanout wiring region 400 at an edge in the first direction is electrically connected with the common signal transmission line 300. For example, the wires 401 of two fanout wiring regions 400 located at both edges among the plurality of fanout wiring regions 400 are all electrically connected with the common signal transmission line 300. For example, the edge here can be an outermost position or a position close to an edge in the fanout wiring region, which is not limited here, and the outermost position is illustratively shown in the accompanying drawings.

As shown in FIGS. 13-15C, the array substrate includes a plurality of first connection structures 710 located between the common signal transmission line 300 and the plurality of fanout wiring regions 400, and the plurality of first connection structures 710 is arranged along the first direction. The wires 401 in at least part of the plurality of fanout wiring regions 400 are electrically connected with the common signal transmission line 300 through the first connection structures 710.

For example, as shown in FIGS. 13-15C, the array substrate further includes a bonding structure 640 located at one side of the fanout wiring region 400 away from the display region 10. For example, the bonding structure 640 includes a plurality of pads used for bonding the circuit board. For example, the wire in one fanout wiring region 400 is electrically connected with one circuit board through the bonding structure 640. For example, the plurality of fanout wiring regions 400 is electrically connected with a plurality of circuit boards in one-to-one correspondence. For example, the circuit board is electrically connected with the common signal transmission line 300 through the wire in the fanout wiring region 400. For example, the first connection structure 710 is electrically connected with the circuit board through the wire in the fanout wiring region 400. For example, the fanout wiring region 400 can be a region, where the fanout wire 401 is located, between the bonding structure 640 and the display region 10. Optionally, the bonding structure can include at least one or more layers of a gate electrode layer, a source-drain electrode layer or an electrode layer (common electrode or pixel electrode), which is not limited here. For example, the plurality of vias shown in the bonding structure 640 is vias connecting different film layers.

For example, as shown in FIGS. 13-15C, each fanout wiring region 400 includes a wire 401 electrically connected with the first connection structure 710, and the plurality of first connection structures 710 is electrically connected with the common signal transmission line 300. The wire 401 is arranged in a partially bent wiring manner to balance the signal line impedance uniformity in the fanout wiring region, thereby improving the display quality.

As shown in FIGS. 13-15C, the number of the plurality of fanout wiring regions 400 is N, the common signal transmission line 300 includes a first transmission portion 310 extending in the first direction and located between the display region 10 and the plurality of fanout wiring regions 400, the length of the first transmission portion 310 is L, and the resistance of the part, with the length of L/2N, of the first transmission portion 310 is not greater than 30 ohms, where N is a positive integer.

In the array substrate provided by the embodiment of the present disclosure, by setting the width and thickness of the first transmission portion to set the resistance of the part with the length of L/2N of the first transmission portion to not greater than 30 ohms, it is helpful to reduce the difference in coupling recovery time of the common voltage at different positions close to the fanout wiring region in the display region and prevent bright block from appearing between adjacent fanout wiring regions, and is helpful to alleviate defects and improve the display effect.

In some examples, as shown in FIGS. 13-15C, the array substrate further includes a base substrate 610, and a plurality of gate lines 620 and a plurality of data lines 630 located on the base substrate 610. The plurality of gate lines 620 is arranged along a second direction, and the second direction intersects with the first direction; the plurality of data lines 630 is arranged along the first direction, the plurality of data lines 630 is located at one side of the plurality of gate lines 620 away from the base substrate 610, and the common electrode 110 is located at one side of the data lines 630 away from the base substrate 610.

In some examples, as shown in FIGS. 13-15C, the plurality of sub-pixels 100 is arrayed along the first direction and the second direction, two sub-pixel columns arranged along the first direction are disposed between adjacent data lines 630, the sub-pixels 100 in each sub-pixel column are arranged along the second direction, different sub-pixels 100 connected with the same data line 630 are connected with different gate lines 620, the plurality of gate lines 620 includes first gate lines and second gate lines alternately arranged along the second direction, and a gate line pair formed by the first gate line and the second gate line is disposed between two adjacent sub-pixels 100 arranged along the second direction; and the plurality of data lines 630 and the plurality of common electrode lines 200 are alternately arranged along the first direction. For example, the data line 630 is electrically connected with the bonding structure 640 through the wire 401 in the fanout wiring region 400 so as to be electrically connected with the circuit board, the common electrode line 200 is electrically connected with the common signal transmission line 300, and the common signal transmission line 300 is electrically connected with the bonding structure 640 through the first connection structure 710 and the wire 401 in the fanout wiring region 400 so as to be electrically connected with the circuit board. For example, the structures at both edges of the common signal transmission line 300 in the first direction can be electrically connected with the bonding structure 640 through the wires 401 in the fanout wiring region 400.

The base substrate, the gate lines and the data lines in the array substrate provided by the present embodiment have the same features as the base substrate, the gate lines and the data lines in the array substrate shown in FIG. 2, and details will not be repeated here.

In some examples, as shown in FIGS. 13-15C, the first transmission portion 310 includes a first conductive layer 311 and a second conductive layer 312 which are stacked, the first conductive layer 311 is disposed in the same layer as the gate line 620, and the second conductive layer 312 is disposed in the same layer as the common electrode 110. For example, the first connection structure 710 can be disposed in the same layer as the first conductive layer 311, and for example, the first connection structure 710 and the first conductive layer 311 can be an integrated structure.

For example, as shown in FIGS. 13-15C, the first transmission portion 310 is a portion of the common signal transmission line 300 extending in the first direction and located between the display region 10 and the fanout wiring region 300. For example, the resistance of the part of the first transmission portion 310 with the length of L/2N is not greater than 29 ohms. For example, the resistance of the part of the first transmission portion 310 with the length of L/2N is not greater than 28 ohms. For example, the resistance of the part of the first transmission portion 310 with the length of L/2N is not greater than 27 ohms. For example, the resistance of the part of the first transmission portion 310 with the length of L/2N is not greater than 26 ohms. For example, the resistance of the part of the first transmission portion 310 with the length of L/2N is not greater than 25 ohms. For example, the resistance of the part of the first transmission portion 310 with the length of L/2N is not greater than 24 ohms. For example, the resistance of the part of the first transmission portion 310 with the length of L/2N is not greater than 23 ohms. For example, the resistance of the part of the first transmission portion 310 with the length of L/2N is not greater than 22 ohms. For example, the resistance of the part of the first transmission portion 310 with the length of L/2N is not greater than 21 ohms. For example, the resistance of the part of the first transmission portion 310 with the length of L/2N is not greater than 20 ohms. For example, the resistance of the part of the first transmission portion 310 with the length of L/2N is not greater than 19 ohms. For example, the resistance of the part of the first transmission portion 310 with the length of L/2N is not greater than 18 ohms. For example, the resistance of the part of the first transmission portion 310 with the length of L/2N is not greater than 17 ohms. For example, the resistance of the part of the first transmission portion 310 with the length of L/2N is not greater than 16 ohms. For example, the resistance of the part of the first transmission portion 310 with the length of L/2N is not greater than 15 ohms. For example, the resistance of the part of the first transmission portion 310 with the length of L/2N is not greater than 14 ohms. For example, the resistance of the part of the first transmission portion 310 with the length of L/2N is not greater than 13 ohms. For example, the resistance of the part of the first transmission portion 310 with the length of L/2N is not greater than 12 ohms. For example, the resistance of the part of the first transmission portion 310 with the length of L/2N is not greater than 11 ohms. For example, the resistance of the part of the first transmission portion 310 with the length of L/2N is not greater than 10 ohms.

By setting the length, width and thickness of the first transmission portion, the impedance of the first transmission portion can be adjusted, which is helpful to improve the in-plane uniformity.

For example, as shown in FIGS. 13-15C, the length of the first transmission portion 310 is L, the width of the first transmission portion 310 can be W, and Rs is the square resistance of the first transmission portion 310, so the resistance of the part of the first transmission portion 310 with the length of L/2N is R=L×Rs/(2N×W). The above Rs is related to the thickness of the first transmission portion 310, e.g., the thickness of the first conductive layer 311 and the thickness of the second conductive layer 312. The greater the thickness of the first transmission portion 310, the smaller the Rs. For example, the width of the first transmission portion 310 can be in the range of 200-300 microns. For example, the width of the first transmission portion 310 can be in the range of 220-280 microns. For example, the width of the first transmission portion 310 can be in the range of 250-275 microns. For example, N can be in the range of 2-20. For example, N can be in the range of 10-18. For example, N can be in the range of 12-16. For example, N can be in the range of 3-6. For example, N can be in the range of 5-7. For example, N can be 4. For example, the ratio of the length L of the first transmission portion 310 to the length of the display region is in the range of 0.8-1.2. For example, the ratio of the length L of the first transmission portion 310 to the length of the display region is in the range of 0.9-1.1. For example, the range of Rs is 0.04-0.1.

As can be seen from the formula of the resistance of the first transmission portion, the greater the width and thickness of the part of the first transmission portion with the length of L/2N or the larger the number of fanout wiring regions, the smaller the resistance of the part of the first transmission portion with the length of L/2N.

For example, as shown in FIGS. 13-15C, at least one first connection structure 710 is electrically connected with two parts of the wires 401, close to each other, in two adjacent fanout wiring regions 400. For example, at least part of the first connection structure 710 is located between adjacent fanout wiring regions 400. For example, two parts of wires located at both edges of the same fanout wiring region 400 are electrically connected with different first connection structures 710, respectively, and two parts of wires 401 located at two edges, close to each other, of two adjacent fanout wiring regions 400 are electrically connected with the same first connection structure 710. For example, the position where each first connection structure 710 is electrically connected with the common signal transmission line 300 is a compensation point.

For example, as shown in FIG. 13, during testing the common voltage waveform of the array substrate, the first connection structure 710 is electrically connected with the common signal transmission line 300 and the resistance of the part with the length of L/2N of the first transmission portion 310 is not greater than 30 ohms, so that the difference in the coupling recovery time of the common voltage at multiple positions of the display region 10 close to the fanout wiring region 400, such as positions P01, P02 and P03, can be relatively small. For example, the coupling amplitude at position P01 is 760 mV, the common voltage waveform recovery time is 2.4 us; the coupling amplitude at position P02 is 760 mV, the common voltage waveform recovery time is 2.4 us; the coupling amplitude at position P03 is 760 mV, and the common voltage waveform recovery time is less than 1 us.

In some examples, as shown in FIGS. 13-15C, the plurality of common electrode lines 200 is electrically connected with the first transmission portion 310 through a plurality of connection blocks 313; in the direction perpendicular to the base substrate 610, the plurality of connection blocks 313 does not overlap with the first conductive layer 311, the plurality of connection blocks 313 overlaps with the second conductive layer 312, and the plurality of connection blocks 313 is electrically connected with the first conductive layer 311 through the second conductive layer 312. The electrical connection relationship between the common electrode line and the first transmission portion and the positional relationship among the connection block, the first conductive layer and the second conductive layer in the present embodiment can have the same features as the of the electrical connection relationship between the common electrode line and the first transmission portion and the positional relationship among the connection block, the first conductive layer and the second conductive layer in the array substrate shown in FIGS. 7-8, and details will not be repeated here.

For example, as shown in FIG. 15B, the shape of at least part of the wires 401 in the fanout wiring region 400 is set to include a bent part and a straight part, and the length of the straight part in different wires 401 is different. By setting the bent part in the wire, it is helpful to reduce the length difference of wires electrically connected with different data lines and improve the display yield.

In some examples, the positional relationship between the connection block and the first conductive layer and the position of the via electrically connecting the connection block and the common transmission signal line in the embodiment of the present disclosure can be the same as the corresponding features in the array substrate shown in FIGS. 9-10, and the embodiment of the present disclosure can adopt the connection mode between the first transmission portion 310 and the common electrode line 200 shown in FIGS. 9-10.

For example, as shown in FIGS. 9-10, the plurality of common electrode lines 200 is electrically connected with the first transmission portion 310 through a plurality of connection blocks 313, and the plurality of connection blocks 313 is disposed in the same layer as the plurality of data lines 620; the orthographic projections of the plurality of connection blocks 313 on the base substrate 610 fall within the orthographic projection of each of the first conductive layer 311 and the second conductive layer 312 on the base substrate 610, and the plurality of connection blocks 313 is electrically connected with the first conductive layer 311 through the second conductive layer 312. By setting the connection block stacked with the first conductive layer, it can avoid the occurrence of groove, which may results in defects, such as the second conductive layer being disconnected, etc., and may further increase the resistance of the common signal transmission line, in the insulating layer at the gap between the connection block and the first conductive layer in the direction parallel to the base substrate.

For example, as shown in FIGS. 9-10, the first transmission portion 310 includes a first edge 3101 and a second edge 3102 extending in the first direction, the first edge 3101 is located at one side of the second edge 3102 close to the display region 10, and the distance between the connection block 313 and the second edge 3102 is less than the distance between the connection block 313 and the first edge 3101. For example, the distance between the via 031 and the second edge 3102 is less than the distance between the via 031 and the first edge 3101, and the distance between the via 032 and the second edge 3102 is less than the distance between the via 032 and the first edge 3101.

In the array substrate provided by the present disclosure, by setting the connection block to be far away from the display region, it is helpful to set the via to be far away from the display region and to improve the flatness of the edge of the display region, thus reducing Mura resulted from PI diffusion defects.

In the array substrate provided by the embodiment of the present disclosure, the arrangement manner of the vias 031 and 032 is the same as the arrangement manner of the vias 031 and 032 in the embodiments shown in FIGS. 9-10, and details will not be repeated here.

The array substrate provided by the present embodiment can adopt the layout arrangement manner shown in FIGS. 11 and 12. The first transmission portion 310 of the common signal transmission line 300 shown in FIG. 11 can be replaced by the first transmission portion 310 shown in FIG. 14. For example, as shown in FIG. 12, the gate driving connection line 651 and the data line 630 can be structures disposed in the same layer, the common signal transmission line 300 further includes a second transmission portion 320 extending in the second direction, the second transmission portion 320 includes a third conductive layer 321 and a fourth conductive layer 322 which are stacked, the third conductive layer 321 and the first conductive layer 311 are an integrated film layer, and the fourth conductive layer 322 and the second conductive layer 312 are an integrated film layer. For example, the first transmission portion 310 and the second transmission portion 320 can be an integrated structure.

For example, the gate driving connection line 651 overlaps with the second transmission portion 320 in the direction perpendicular to the base substrate, and the gate driving connection line 651 passes through the second transmission portion 320 and is electrically connected with the gate line 620 through a transfer structure 621.

In the array substrate provided by the present disclosure, by setting the second transmission portion in the common signal transmission line into a structure integrated with the first transmission portion, it is helpful to omit the transfer via electrically connecting the first transmission portion and the second transmission portion, and further reduce the resistance of the common signal transmission line.

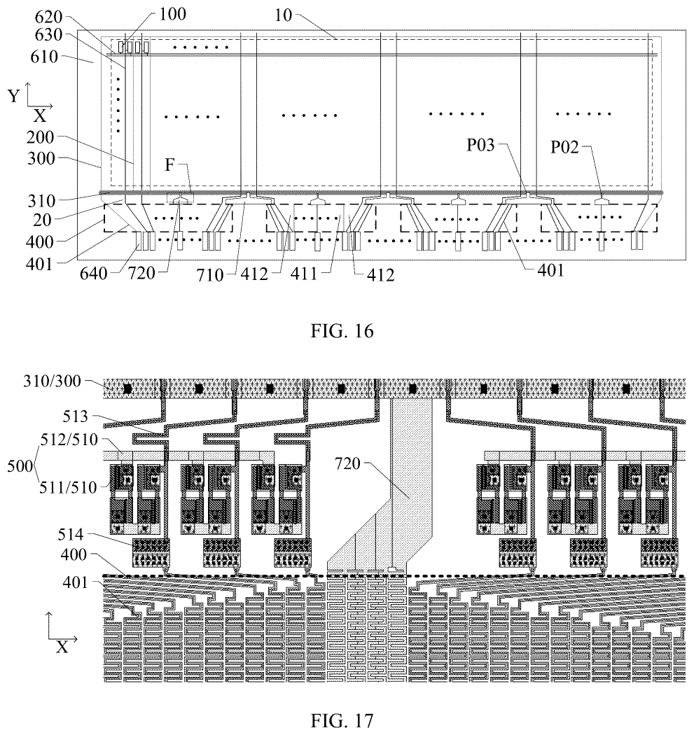

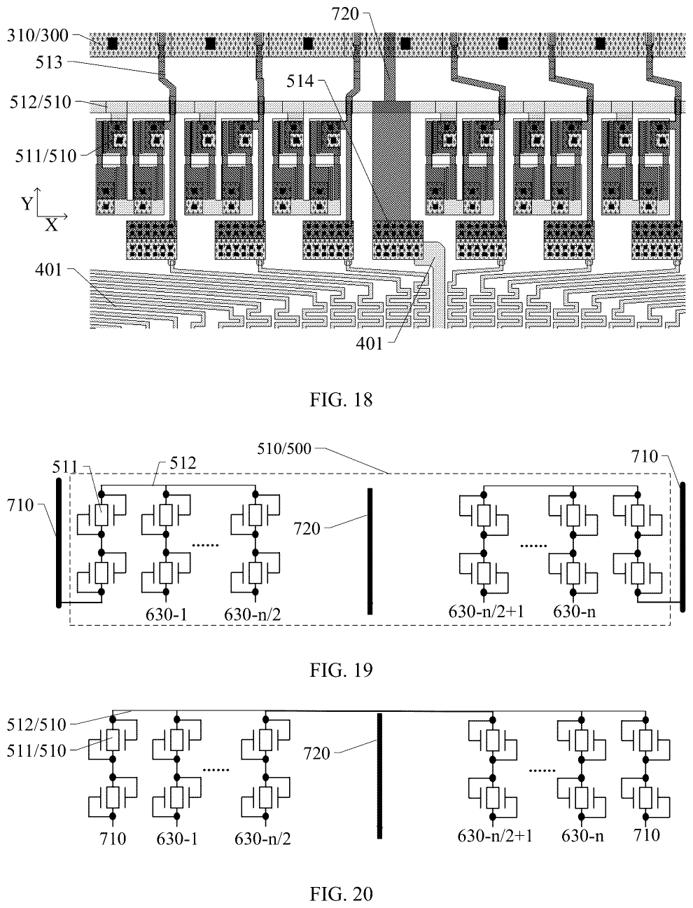

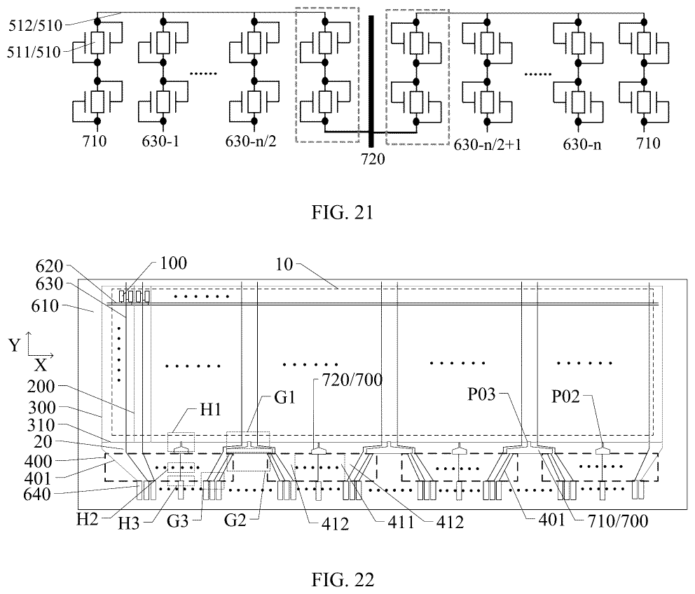

FIG. 16 is a partial planar structural view of an array substrate provided by another example of the embodiment of the present disclosure, FIGS. 17 and 18 are partial enlarged views of region F shown in FIG. 16 in different examples, FIG. 19 is a circuit diagram of one electrostatic discharge unit group shown in FIG. 17, FIG. 20 is a circuit diagram of one electrostatic discharge unit group shown in FIG. 18, and FIG. 21 is a circuit diagram of one electrostatic discharge unit group shown in another example.

The array substrate shown in FIG. 16 is different from the array substrate shown in FIG. 13 in that the array substrate shown in FIG. 16 further includes a second connection structure 720.

In some examples, as shown in FIG. 16, each fanout wiring region 400 includes a middle region 411 and edge regions 412 located at both sides of the middle region 411 in the first direction, and the plurality of first connection structures 710 is electrically connected with wires 401 in the edge region 412 of at least part of the fanout wiring regions 400; the array substrate further includes a plurality of second connection structures 720 located between the common signal transmission line 300 and the plurality of fanout wiring regions 400, and the plurality of second connection structures 720 are arranged along the first direction; wires 401 in the middle region 411 of at least part of the plurality of fanout wiring regions 400 are electrically connected with the common signal transmission line 300 through the plurality of second connection structures 720. For example, the wires 401 in one fanout wiring region 400 can be electrically connected with 0, 1, 2, 3 or more second connection structures 720. For example, wires 401 in different fanout wiring regions 400 can be electrically connected with the same number of second connection structures 720, but it is not limited thereto, and wires in different fanout wiring regions can also be electrically connected with different numbers of second connection structures 720. Referring to FIG. 16, optionally, in the present disclosure, the wire 401, the second connection structure 720, the first connection structure 710, etc., are all provided with a common voltage signal by the same total signal source, and the total signal source for providing signals can be optionally set on a printed circuit board are optionally arranged on the printed circuit board. In the case where the second connection structure is disposed in the middle region of one fanout wiring region, the wiring region corresponding to the circuit board (optionally, flexible printed circuit board) bonded to the array substrate includes a signal line for transmitting common voltage, which is configured to be electrically connected with the second connection structure. In this case, in the flexible printed circuit board, the signal line for transmitting common voltage can pass through the source driver chip disposed on the flexible printed circuit board or bypass the source driver chip, and be electrically connected with the final total signal source; the printed circuit board is electrically connected with the flexible printed circuit board, and the flexible printed circuit board is electrically connected with the display panel, thereby realizing signal transmission. Referring to FIG. 17, the design that the second connection structure close to the common signal transmission line is set as a whole block in FIG. 17 can reduce the impedance of the transmission signal line, while the wires 401 are partially designed to be bent and have a gap therebetween, which is beneficial to the curing of frame sealant at a position corresponding to the frame sealant.

In the array substrate provided by the present example, the resistance of the first transmission portion is set, and at the same time, the second connection structure is set to increase the common signal compensation points, which is helpful to reduce the difference in the coupling recovery time of the common signal at different positions of the display region close to the fanout wiring region, such as position P03 of the display region opposite to the gap between the fanout wiring regions and position P02 of the display region opposite to the fanout wiring region, and to improve the yield of the array substrate.

The above-mentioned middle region and edge region refer to the relative positional relationship of different regions. In the same fanout wiring region, the middle region is located between two edge regions. For example, the areas of the edge regions at both sides of the middle region are equal, and the area ratio of the middle region to the edge region can be in the range of 0.01-100. For example, the area ratio of the middle region to the edge region can be in the range of 0.1-10. For example, the area ratio of the middle region to the edge region can be in the range of 0.5-5, etc.

In some examples, as shown in FIG. 16, at least one first connection structure 710 is electrically connected with the wires 401 in two edge regions 412, close to each other, of two adjacent fanout wiring regions 400. For example, each first connection structure 710 is electrically connected with two parts of the wires 401 in two edge regions 412, close to each other, of two adjacent fanout wiring regions 400.

For example, as shown in FIG. 16, the second connection structure 720 can have equal or unequal distances to the two first connection structures 710 located at both sides of the second connection structure 720.

The first connection structures in the array substrate shown in FIG. 16 can have the same features as the first connection structures in the array substrate shown in FIGS. 13-14.

Compared with the array substrate shown in FIG. 13, the array substrate shown in FIG. 16 adds a second connection structure 720 between the common signal transmission line 300 and the middle region 412 of the fanout wiring region 400, so that a wire now electrically connected with the second connection structure 720 is disposed at a position of the wire 401, which was originally electrically connected with the data line 630, in the middle region 412 of the fanout wiring region 400, and the pad, which was originally electrically connected with the data line 630, in the bonding structure 640 is now electrically connected with the second connection structure 720, so that the wires 401 electrically connected with the data lines 630 in the same fanout wiring region 400 of the array substrate shown in FIG. 16 are located at both sides of the wire 401 electrically connected with the second connection structure 720, and the pads electrically connected with the data lines 630 in the bonding structure 640 corresponding to the same fanout wiring region 400 are located at both sides of the pad electrically connected with the second connection structure 720.

For example, FIG. 17 illustratively shows the boundary of the fanout wiring region 400 facing the common signal transmission line 300, and the second connection structure 720 can be electrically connected with four wires 401 so as to be electrically connected with four pads in the bonding structure 640. For example, the four wires 401 electrically connected with the second connection structure 720 are electrically connected together, and for example, the four wires 401 and the second connection structure 720 are an integrated structure. For example, the wire 401 electrically connected with the second connection structure 720 and the wire 401 electrically connected with the data line 630 can have the same shape, such as a bent shape, which is helpful to avoid a large difference in local etching solution concentration during the formation of the wires and improve the etching uniformity.

In some examples, as shown in FIGS. 16-21, the array substrate further includes an electrostatic discharge structure 500 located in the non-display region 20, the electrostatic discharge structure 500 is located between the common signal transmission line 300 and the plurality of fanout wiring regions 400, the electrostatic discharge structure 500 includes a plurality of electrostatic discharge unit groups 510, each electrostatic discharge unit group 510 includes a plurality of electrostatic discharge units 511 and a connection wire 512 connecting the plurality of electrostatic discharge units 511, and at least part of the plurality of electrostatic discharge units 511 is electrically connected with the plurality of data lines 630. The specific structure of the electrostatic discharge unit 511 in the present embodiment can be the same as that of the electrostatic discharge unit 511 shown in FIG. 5, and details will not be repeated here.

In some examples, as shown in FIGS. 14, 16, 17 and 19, the plurality of first connection structures 710 passes through gaps between the plurality of electrostatic discharge unit groups 510 so as to be electrically connected with the common signal transmission line 300, and the plurality of second connection structures 720 passes through gaps between the plurality of electrostatic discharge units 511 so as to be electrically connected with the common signal transmission line 300; and at least one of the plurality of first connection structures 710 is electrically connected with the electrostatic discharge structure 500.

For example, as shown in FIGS. 14, 16, 17 and 19, the data line 630 is electrically connected with the electrostatic discharge unit 511 through a data line connection line 513, and the data line connection line 513 and the data line 630 can be structures disposed in the same layer. For example, the data line connection line 513 and the data line 630 can be an integrated structure. For example, the data line connection line 513 is electrically connected with the wire 401 in the fanout wiring region through a transfer portion 514. For example, the data line connection lines 513 electrically connected with different electrostatic discharge units 511 can have the same shape, such as a polyline structure including three segments. For example, the data line connection lines 513 electrically connected with the electrostatic discharge units 511 located at both sides of the second connection structure 720 can have different shapes; for example, the number of segments included in the data line connection lines 513 located at one side of the second connection structure 720 is less than the number of segments included in the data line connection lines 513 located at the other side of the second connection structure 720; for example, the length of the data line connection line 513 located at one side of the second connection structure 720 is greater than the length of the data line connection lines 513 located at the other side of the second connection structure 720. By adjusting the lengths of data line connection lines electrically connected with different electrostatic discharge units, it is helpful to reduce the difference in the sum of the lengths of the wire and data line connection line electrically connected with different data lines, so as to reduce the signal delay difference on data lines.

For example, as shown in FIGS. 14, 16, 17 and 19, the data line connection line 513 and the wire 401 are structures disposed in different layers. For example, the wire 401 and the gate line 620 are structures disposed in the same layer.

For example, as shown in FIGS. 14, 16, 17 and 19, each fanout wiring region 400 corresponds to one electrostatic discharge unit group 510, the plurality of wires 401 electrically connected with the data lines 630 in each fanout wiring region 400 is electrically connected with the same electrostatic discharge unit group 510, and the plurality of wires 401 electrically connected with the data lines 630 in different fanout wiring regions 400 are electrically connected with different electrostatic discharge unit groups 510. For example, the first connection structure 710 is electrically connected with the electrostatic discharge units 511 located at both sides thereof. For example, the first connection structure 710 passes through the gap between two connection wires 512 in adjacent electrostatic discharge unit groups 510 so as to be electrically connected with the common signal transmission line 300.

In some examples, as shown in FIGS. 14, 16, 17 and 19, the first connection structure 710, the second connection structure 720 and the first conductive layer 311 of the common signal transmission line 300 are an integrated structure; the connection wire 512 is disposed in the same layer as the first conductive layer 311 of the common signal transmission line 300, and the connection wire 512 is separated from the second connection structure 720, so as to prevent the connection wire 512 from being short-circuited with the second connection structure 720.

For example, as shown in FIGS. 14, 16, 17 and 19, one fanout wiring region 400 corresponds to two connection wires 512, and the second connection structure 720 is disposed between two connection wires 512.

In some examples, as shown in FIGS. 14, 16, 17 and 19, two electrostatic discharge units 511 located at both sides of each second connection structure 720 and immediately adjacent to the each second connection structure 720 are both electrically connected with the data lines 630. For example, two electrostatic discharge units 511 located at both sides of the second connection structure 720 and immediately adjacent to the second connection structure 720 are not directly connected with the second connection structure 720.

In some examples, as shown in FIGS. 14, 16, 18 and 20, the first connection structure 710 and the first conductive layer 311 of the common signal transmission line 300 are an integrated structure, and the connection wire 512 is disposed in the same layer as the first conductive layer 311 of the common signal transmission line 300; in the direction perpendicular to the base substrate 610, the second connection structure 720 overlaps with the common signal transmission line 300, and the second connection structure 720 is electrically connected with the common signal transmission line 300 through a via in the insulating layer between the second connection structure 720 and the common signal transmission line 300. For example, the second connection structure and the connection wire 512 are structures disposed in different layers. In the array substrate provided by the present example, the second connection structure and the connection wires are structures disposed in different layers, which is helpful to avoid short circuit between the second connection structure and the connection wire.

For example, as shown in FIGS. 14, 16, 18 and 20, the second connection structure 720 and the data line 630 are structures disposed in the same layer, the second connection structure 720 overlaps with the connection wire 512 in the direction perpendicular to the base substrate 610, and the connection wires 720 located at both sides of the second connection structure 720 can be an integrated wire without being disconnected at the position of the second connection structure 720. For example, the second connection structure 720 is electrically connected with the wire 401 of the fanout wiring region 400 through a transfer portion 514. For example, the transfer portion 514 includes three film layers, e.g., a first sub-film layer disposed in the same layer as the data line 630, a second sub-film layer disposed in the same layer as the gate line 620 and a third sub-film layer disposed in the same layer as the common electrode 110. In the direction perpendicular to the base substrate, both the first sub-film layer and the second sub-film layer overlap with the third sub-film, but the first sub-film layer does not overlap with the second sub-film; the first sub-film layer is electrically connected with the third sub-film layer through the via in the insulating layer between the first sub-film layer and the third sub-film layer, and the second sub-film layer is electrically connected with the third sub-film layer through the via in the insulating layer between the second sub-film layer and the third sub-film layer, so that the transfer connection between the second connection structure or the data line connection line and the wire in the fanout wiring region is realized.

In the array substrate provided by the present example, both the second connection structure and the data line connection line are electrically connected with the wires in the fanout wiring region through the transfer portions, thus improving the etching uniformity of vias.

For example, as shown in FIGS. 14, 16, 18 and 20, the same fanout wiring region 400 corresponds to one connection wire 512.

For example, as shown in FIGS. 14, 16, 18 and 20, two electrostatic discharge units 511 located at both sides of each second connection structure 720 and immediately adjacent to the each second connection structure 720 are both electrically connected with the data lines 630. For example, two electrostatic discharge units 511 located at both sides of the second connection structure 720 and immediately adjacent to the second connection structure 720 are not directly connected with the second connection structure 720.

For example, the circuit shown in FIG. 21 is different from the circuit shown in FIGS. 19-20 in that the second connection structure 720 is electrically connected with the electrostatic discharge unit 511. For example, as shown in FIG. 21, the position of the second connection structure 720 can be set according to the position of the electrostatic discharge unit 511 in the array substrate; for example, the electrostatic discharge units 511 located at both sides of the second connection structure 720 can be directly connected with the second connection structure 720.

FIGS. 19-21 illustratively show that wires in one fanout wiring region are electrically connected with n data lines, and the second connection structure is located between an electrostatic discharge unit connected with the (n/2)-th data line and an electrostatic discharge unit connected with the (n/2+1)-th data line. But it is not limited thereto, and the second connection structure can also be located between electrostatic discharge units connected with two adjacent data lines at other positions. For example, the number of data lines 630 corresponding to one fanout wiring region 400 is n, and the n data lines 630 corresponding to one fanout wiring region 400 are respectively connected with n electrostatic discharge units 511, and then are connected in parallel through a connection wire 512; and the two electrostatic discharge units 511 located at two edges are respectively electrically connected with the first connection structures 710 located at both sides.

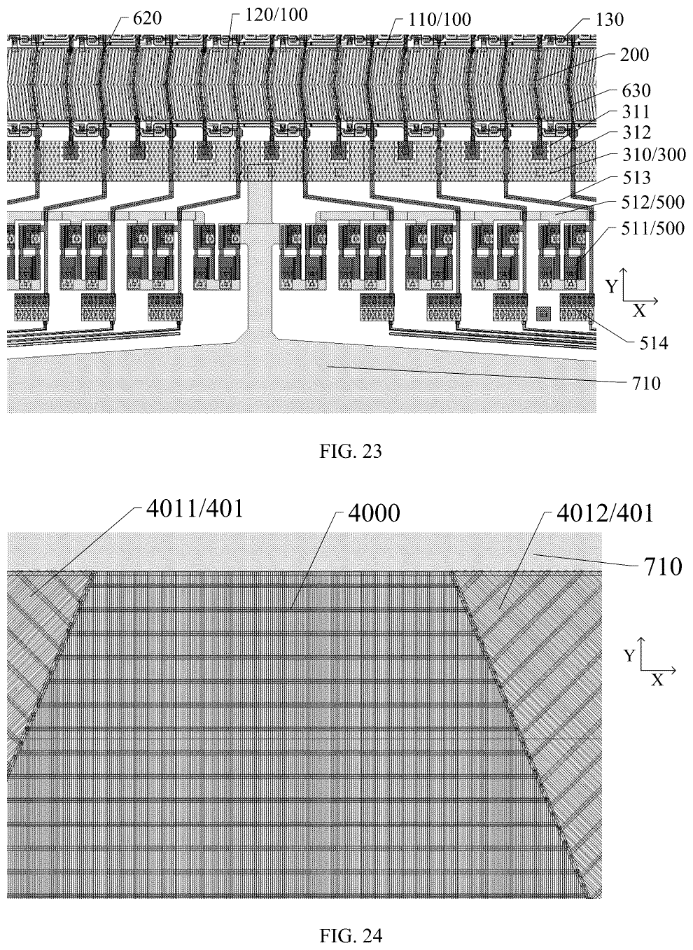

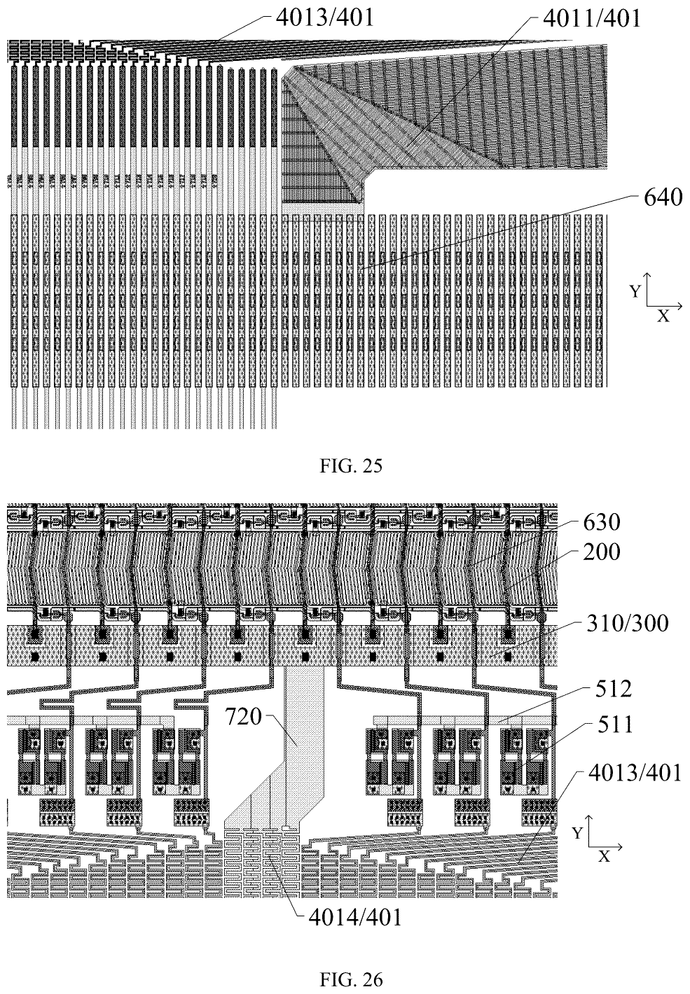

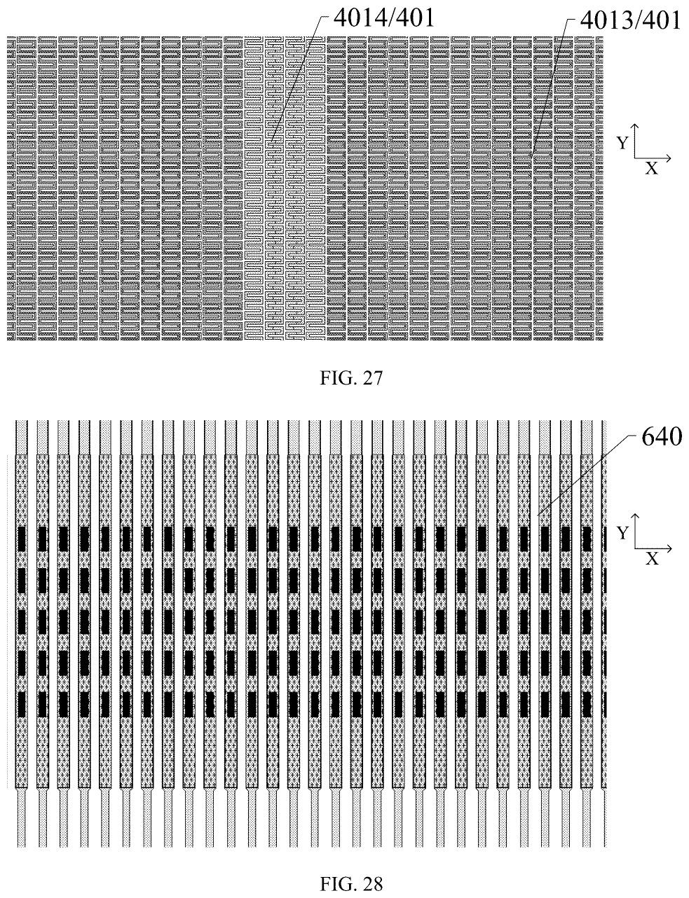

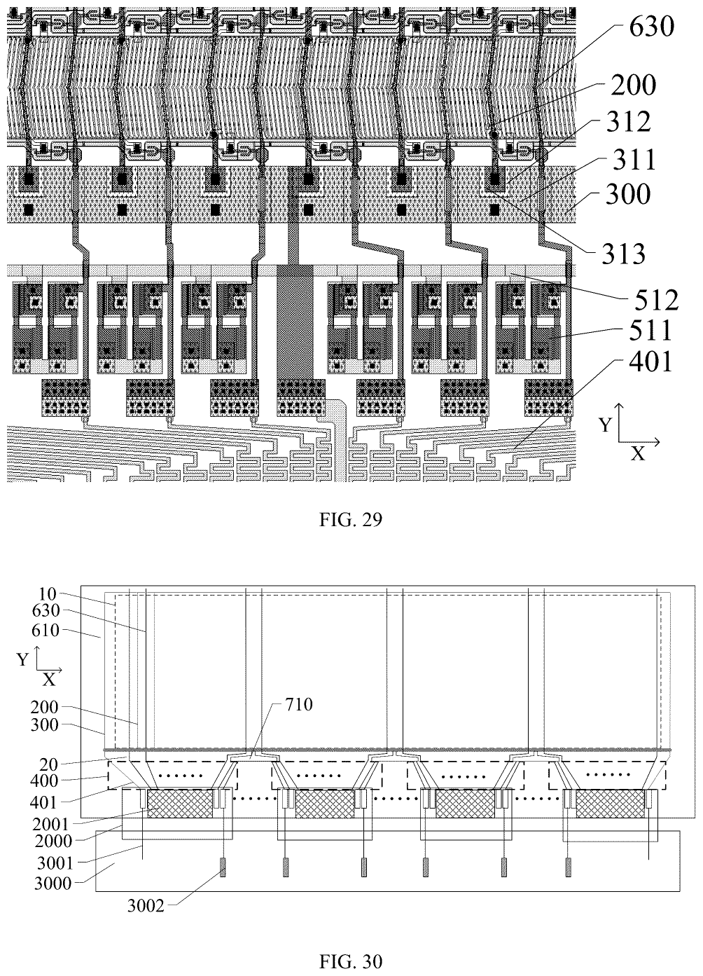

FIG. 22 is a partial planar structural view of an array substrate provided by another embodiment of the present disclosure; FIG. 23 is a partial enlarged view of region G1 in the array substrate shown in FIG. 22; FIG. 24 is a partial enlarged view of region G2 in the array substrate shown in FIG. 22; FIG. 25 is a partial enlarged view of region G3 in the array substrate shown in FIG. 22; FIGS. 26 and 29 are partial enlarged views of region H1 of the array substrate shown in FIG. 22 in different examples; FIG. 27 is a partial enlarged view of region H2 of the array substrate shown in FIG. 22; and FIG. 28 is a partial enlarged view of region H3 of the array substrate shown in FIG. 22.

As shown in FIGS. 22-28, the array substrate includes a display region 10 and a non-display region 20 located on at least one side of the display region 10. The display region 10 shown in FIG. 22 can have the same features as the display region 10 shown in FIG. 2, and details will not be repeated here.

As shown in FIGS. 22-28, the array substrate includes a plurality of sub-pixels 100, at least part of the plurality of sub-pixels 100 is located in the display region 10, and the sub-pixels 100 located in the display region 10 include a common electrode 110. For example, the sub-pixel 100 further includes a pixel electrode 120 and a switching structure 130. The sub-pixels in the array substrate provided by the present embodiment have the same features as the sub-pixels in the array substrate shown in FIG. 2, and details will not be repeated here.

As shown in FIGS. 22-28, the array substrate includes a plurality of common electrode lines 200, a common signal transmission line 300 and a plurality of fanout wiring regions 400. The plurality of common electrode lines 200 is located in the display region 10 and electrically connected with the common electrode 110 of the sub-pixels 100, and the plurality of common electrode lines 200 is arranged along the first direction. The common signal transmission line 300 is disposed in the non-display region 20 and electrically connected with the plurality of common electrode lines 200; the plurality of fanout wiring regions 400 is located in the non-display region 20, and the plurality of fanout wiring regions 400 is arranged along the first direction.

The common electrode lines in the array substrate provided by the present embodiment have the same features as the common electrode lines in the array substrate shown in FIG. 2, and details will not be repeated here.

For example, the plurality of fanout wiring regions 400 is located at one side of the display region 10 in the second direction. For example, FIG. 22 illustratively shows four fanout wiring regions 400, but it is not limited thereto, and the number of fanout wiring regions can be set according to product requirements and product size. For example, each fanout wiring region 400 includes a plurality of wires 401.

As shown in FIGS. 22-28, among the plurality of fanout wiring regions 400, a wire 401 located in the fanout wiring region 400 at an edge in the first direction is electrically connected with the common signal transmission line 300. For example, the wires 401 of two fanout wiring regions 400 located at both edges among the plurality of fanout wiring regions 400 are electrically connected with the common signal transmission line 300. For example, the edge here can be an outermost position or a position close to an edge in the fanout wiring region, which is not limited here, and the outermost position is illustratively shown in the accompanying drawings.

As shown in FIGS. 22-28, the array substrate includes a plurality of connection structures 700 located between the common signal transmission line 300 and the fanout wiring region 400, and the plurality of connection structures 700 is arranged along the first direction; the fanout wiring region 400 includes a middle region 411 and edge regions 412 located at both sides of the middle region 411 in the first direction, a wire 401 in the middle region 411 of the fanout wiring region 400 is electrically connected with the common signal transmission line 300 through at least one connection structure 700 among the plurality of connection structures 700.

By setting the connection structure connected with the middle region of the fanout wiring region, it is helpful to adjust the positions of the compensation points of the circuit board to the array substrate, e.g., increasing the number of compensation points of the circuit board to the array substrate, and it is helpful to reduce the coupling recovery time of the common voltage at different positions in the region of the array substrate close to the circuit board, reduce the probability of display defect and improve the display effect.

In some examples, as shown in FIGS. 22 to 28, the plurality of connection structures 700 includes a plurality of first connection structures 710 located between the common signal transmission line 300 and the plurality of fanout wiring regions 400, and the plurality of first connection structures 710 is arranged along the first direction. The wires 401 in at least part of the plurality of fanout wiring regions 400 are electrically connected with the common signal transmission line 300 through the first connection structures 710.

As shown in FIGS. 22-28, the plurality of first connection structures 710 is electrically connected with wires 401 in the edge region 412 of at least part of the fanout wiring regions 400; the plurality of connection structures 700 further includes a plurality of second connection structures 720 located between the common signal transmission line 300 and the plurality of fanout wiring regions 400, and the plurality of second connection structures 720 are arranged along the first direction; wires 401 in the middle region 411 of at least part of the plurality of fanout wiring regions 400 are electrically connected with the common signal transmission line 300 through the plurality of second connection structures 720. For example, the wires 401 in one fanout wiring region 400 can be electrically connected with 0, 1, 2, 3 or more second connection structures 720. For example, wires 401 in different fanout wiring regions 400 can be electrically connected with the same number of second connection structures 720, but it is not limited thereto, and wires in different fanout wiring regions can also be electrically connected with different numbers of second connection structures 720.

In the array substrate provided by the embodiment of the present disclosure, by setting the first connection structures and the second connection structures to increase the common signal compensation points, it is helpful to reduce the difference in the coupling recovery time of the common signal at different positions of the display region close to the fanout wiring region, such as position P03 of the display region opposite to the gap between the fanout wiring regions and position P02 of the display region opposite to the fanout wiring region, and to improve the yield of the array substrate.

The above-mentioned middle region and edge region refer to the relative positional relationship of different regions. In the same fanout wiring region, the middle region is located between two edge regions. For example, the areas of the edge regions at both sides of the middle region are equal, and the area ratio of the middle region to the edge region can be in the range of 0.01-100. For example, the area ratio of the middle region to the edge region can be in the range of 0.1-10. For example, the area ratio of the middle region to the edge region can be in the range of 0.5-5, etc.

For example, as shown in FIGS. 22-28, the array substrate further includes a bonding structure 640 located at one side of the fanout wiring region 400 away from the display region 10. For example, the bonding structure 640 includes a plurality of pads used for bonding the circuit board. For example, the wire in one fanout wiring region 400 is electrically connected with one circuit board through the bonding structure 640. For example, the plurality of fanout wiring regions 400 is electrically connected with a plurality of circuit boards in one-to-one correspondence. For example, the circuit board is electrically connected with the common signal transmission line 300 through the wire in the fanout wiring region 400. For example, the first connection structure 710 is electrically connected with the circuit board through the wire in the fanout wiring region 400. For example, the fanout wiring region 400 can be a region, where the fanout wire 401 is located, between the bonding structure 640 and the display region 10.

For example, as shown in FIGS. 22-23, each fanout wiring region 400 includes a wire 401 electrically connected with the first connection structure 710, and the plurality of first connection structures 710 is electrically connected with the common signal transmission line 300. For example, each fanout routing region 400 includes a wire 401 electrically connected with the second connection structure 720, and the plurality of second connection structures 720 is electrically connected with the common signal transmission line 300.

In some examples, as shown in FIGS. 22-23, at least one first connection structure 710 is electrically connected with the wires 401 in two edge regions 412, close to each other, of two adjacent fanout wiring regions 400. For example, each first connection structure 710 is electrically connected with two parts of the wires 401 in two edge regions 412, close to each other, of two adjacent fanout wiring regions 400.

For example, as shown in FIG. 22, the second connection structure 720 can have equal or unequal distances to the two first connection structures 710 located at both sides of the second connection structure 720.

In some examples, as shown in FIGS. 22-23, the array substrate further includes a base substrate 610, and a plurality of gate lines 620 and a plurality of data lines 630 located on the base substrate 610. The plurality of gate lines 620 is arranged along a second direction, and the second direction intersects with the first direction; the plurality of data lines 630 is arranged along the first direction, the plurality of data lines 630 is located at one side of the plurality of gate lines 620 away from the base substrate 610, and the common electrode 110 is located at one side of the data lines 630 away from the base substrate 610.

For example, as shown in FIGS. 22-23, the plurality of sub-pixels 100 is arrayed along the first direction and the second direction, two sub-pixel columns arranged along the first direction are disposed between adjacent data lines 630, the sub-pixels 100 in each sub-pixel column are arranged along the second direction, different sub-pixels 100 connected with a same data line 630 are connected with different gate lines 620, the plurality of gate lines 620 includes first gate lines and second gate lines alternately arranged along the second direction, and a gate line pair formed by the first gate line and the second gate line is disposed between two adjacent sub-pixels 100 arranged along the second direction; and the plurality of data lines 630 and the plurality of common electrode lines 200 are alternately arranged along the first direction. For example, the data line 630 is electrically connected with the bonding structure 640 through the wire 401 in the fanout wiring region 400 so as to be electrically connected with the circuit board, the common electrode line 200 is electrically connected with the common signal transmission line 300, and the common signal transmission line 300 is electrically connected with the bonding structure 640 through the first connection structure 710 and the wire 401 in the fanout wiring region 400 so as to be electrically connected with the circuit board. For example, the structures at both edges of the common signal transmission line 300 in the first direction can be electrically connected with the bonding structure 640 through the wires 401 in the fanout wiring region 400.

The base substrate, the gate lines and the data lines in the array substrate provided by the present embodiment have the same features as the base substrate, the gate lines and the data lines in the array substrate shown in FIG. 2, and details will not be repeated here.

In some examples, as shown in FIGS. 23 and 26, the array substrate further includes an electrostatic discharge structure 500 located in the non-display region 20, and the electrostatic discharge structure 500 is located between the common signal transmission line 300 and the plurality of fanout wiring regions 400. For example, the fanout wiring region 400 is located between the electrostatic discharge structure 500 and the bonding structure 640.

In some examples, as shown in FIGS. 23 and 26, the electrostatic discharge structure 500 includes a plurality of electrostatic discharge unit groups 510. Each electrostatic discharge unit group 510 includes a plurality of electrostatic discharge units 511 and a connection wire 512 connecting the plurality of electrostatic discharge units 511, and at least part of the plurality of electrostatic discharge units 511 is electrically connected with the plurality of data lines 630. The specific structure of the electrostatic discharge unit 511 in the present embodiment can be the same as that of the electrostatic discharge unit 511 shown in FIG. 5, and details will not be repeated here.

The circuit diagram of the electrostatic discharge structure unit group provided by the present embodiment can be the same as the circuit diagram of any electrostatic discharge unit group shown in FIGS. 19-21.

In some examples, as shown in FIGS. 23, 26 and 19-21, the plurality of first connection structures 710 passes through gaps between the plurality of electrostatic discharge unit groups 510 so as to be electrically connected with the common signal transmission line 300, and the plurality of second connection structures 720 passes through gaps between the plurality of electrostatic discharge units 511 so as to be electrically connected with the common signal transmission line 300; and at least one of the plurality of first connection structures 710 is electrically connected with the electrostatic discharge structure 500.

For example, as shown in FIGS. 23, 26 and 19-21, the data line 630 is electrically connected with the electrostatic discharge unit 511 through a data line connection line 513, and the data line connection line 513 and the data line 630 can be structures disposed in the same layer. For example, the data line connection line 513 and the data line 630 can be an integrated structure. For example, the data line connection line 513 is electrically connected with the wire 401 in the fanout wiring region through a transfer portion 514. For example, the data line connection lines 513 electrically connected with different electrostatic discharge units 511 can have the same shape, such as a polyline structure including three segments. For example, the data line connection lines 513 electrically connected with the electrostatic discharge units 511 located at both sides of the second connection structure 720 can have different shapes; for example, the number of segments included in the data line connection lines 513 located at one side of the second connection structure 720 is less than the number of segments included in the data line connection lines 513 located at the other side of the second connection structure 720; for example, the length of the data line connection line 513 located at one side of the second connection structure 720 is greater than the length of the data line connection lines 513 located at the other side of the second connection structure 720. By adjusting the lengths of data line connection lines electrically connected with different electrostatic discharge units, it is helpful to reduce the difference in the sum of the lengths of the wire and data line connection line electrically connected with different data lines, so as to reduce the signal delay difference on data lines.

For example, as shown in FIGS. 23, 26 and 19-21, the data line connection line 513 and the wire 401 are structures disposed in different layers. For example, the wire 401 and the gate line 620 are structures disposed in the same layer.

For example, as shown in FIGS. 23, 26 and 19-21, each fanout wiring region 400 corresponds to one electrostatic discharge unit group 510, the plurality of wires 401 electrically connected with the data lines 630 in each fanout wiring region 400 is electrically connected with the same electrostatic discharge unit group 510, and the plurality of wires 401 electrically connected with the data lines 630 in different fanout wiring regions 400 are electrically connected with different electrostatic discharge unit groups 510. For example, the first connection structure 710 is electrically connected with the electrostatic discharge units 511 located at both sides thereof. For example, the first connection structure 710 passes through the gap between two connection wires 512 in adjacent electrostatic discharge unit groups 510 so as to be electrically connected with the common signal transmission line 300.

In some examples, as shown in FIGS. 22, 23 and 26, the wires 401 in each fanout wiring region 400 are electrically connected with one electrostatic discharge unit group 510, and at least one second connection structure 720 is disposed in a plurality of gaps among the plurality of electrostatic discharge units 511 in at least one electrostatic discharge unit group 510.

In some examples, as shown in FIGS. 23, 26 and 19-21, two electrostatic discharge units 511 located at both sides of each second connection structure 720 and immediately adjacent to the each second connection structure 720 are both electrically connected with the data lines 630. For example, two electrostatic discharge units 511 located at both sides of the second connection structure 720 and immediately adjacent to the second connection structure 720 are not directly connected with the second connection structure 720. Of course, the embodiment of the present disclosure is not limited thereto. According to the layout design space of the array substrate, two electrostatic discharge units located at both sides of the second connection structure and immediately adjacent to the second connection structure can be directly connected with the second connection structure.

In some examples, as shown in FIGS. 22, 23 and 26, the common signal transmission line 300 includes a first transmission portion 310 extending in the first direction and located between the display region 10 and the plurality of fanout wiring regions 400, the first transmission portion 310 includes a first conductive layer 311 and a second conductive layer 312 which are stacked, the first conductive layer 311 is disposed in the same layer as the gate line 620, and the second conductive layer 312 is disposed in the same layer as the common electrode 110.

In some examples, as shown in FIGS. 23 and 26, the first connection structure 710, the second connection structure 720 and the first conductive layer 311 of the common signal transmission line 300 are an integrated structure; the connection wire 512 is disposed in the same layer as the first conductive layer 311 of the common signal transmission line 300, and the connection wire 512 is separated from the second connection structure 720, so as to prevent the connection wire 512 from being short-circuited with the second connection structure 720.

For example, as shown in FIGS. 23, 26, 17 and 19, one fanout wiring region 400 corresponds to two connection wires 512, and a second connection structure 720 is disposed between two connection wires 512.

For example, as shown in FIG. 23-25, one side of the first connection structure 710 away from the common signal transmission line 300 is electrically connected with the wire 4011 and the wire 4012 respectively in two fanout wiring regions, a conductive line 4000 is disposed between the two wires 4011 and 4012, and the wire 4011 and the wire 4012 are electrically connected through the conductive line 4000. For example, the wire 4011 can be electrically connected with eight pads in the bonding structure 640 (the specific number of pads is not limited here). The wire 4011 and the wire 4012 can have different extending directions, and each wire includes a plurality of signal lines connected together in a grid shape. For example, a plurality of wires 401 disposed at one side of the wire 4011 away from the conductive line 4000 includes a wire 4013 electrically connected with the data line 630 and a wire 4014 electrically connected with the second connection structure. Referring to FIG. 25, the wires 4011 here are equivalent to the outermost wires in the fanout wiring region corresponding to the wires 4013, and the wires 4011 realize the connection with the common signal transmission line 300. Similarly, the wires 4012 will be electrically connected with the pads corresponding to a fanout wire adjacent to the fanout wire corresponding to the wires 4011, that is, the wires 4012 are signal lines at the edge of another fanout wiring region.

For example, as shown in FIGS. 26-28, the second connection structure 720 can be electrically connected with four wires 4014 so as to be electrically connected with four pads in the bonding structure 640. For example, the four wires 4014 electrically connected with the second connection structure 720 are electrically connected together, and for example, the four wires 4014 and the second connection structure 720 are an integrated structure. For example, the wire 4014 electrically connected with the second connection structure 720 and the wire 4013 electrically connected with the data line 630 can have the same shape, such as a bent shape. By setting the wires in the fanout wiring region to be bent, it is helpful to reduce the difference in the sum of the lengths of different wires and data line connection lines.

The array substrate shown in FIG. 29 is different from the array substrate shown in FIG. 26 in that the second connection structure 720 adopts different film layers.

In some examples, as shown in FIGS. 22 and 29, the first connection structure 710 and the first conductive layer 311 of the common signal transmission line 300 are an integrated structure, and the connection wire 512 is disposed in the same layer as the first conductive layer 311 of the common signal transmission line 300; in the direction perpendicular to the base substrate 610, the second connection structure 720 overlaps with the common signal transmission line 300, and the second connection structure 720 is electrically connected with the common signal transmission line 300 through a via in the insulating layer between the second connection structure 720 and the common signal transmission line 300. In the array substrate provided by the present example, the second connection structure and the connection wires are structures disposed in different layers, which is helpful to avoid short circuit between the second connection structure and the connection wire.

For example, as shown in FIGS. 22 and 29, the second connection structure 720 and the data line 630 are structures disposed in the same layer, the second connection structure 720 overlaps with the connection wire 512 in the direction perpendicular to the base substrate 610, and the connection wires 720 located at both sides of the second connection structure 720 can be an integrated wire without being disconnected at the position of the second connection structure 720. For example, the second connection structure 720 is electrically connected with the wire 401 of the fanout wiring region 400 through a transfer portion 514. For example, the transfer portion 514 includes three film layers, e.g., a first sub-film layer disposed in the same layer as the data line 630, a second sub-film layer disposed in the same layer as the gate line 620 and a third sub-film layer disposed in the same layer as the common electrode 110. In the direction perpendicular to the base substrate, both the first sub-film layer and the second sub-film layer overlap with the third sub-film, but the first sub-film layer does not overlap with the second sub-film; the first sub-film layer is electrically connected with the third sub-film layer through the via in the insulating layer between the first sub-film layer and the third sub-film layer, and the second sub-film layer is electrically connected with the third sub-film layer through the via in the insulating layer between the second sub-film layer and the third sub-film layer, so that the transfer connection between the second connection structure or the data line connection line and the wire in the fanout wiring region is realized.

In the array substrate provided by the present example, both the second connection structure and the data line connection line are electrically connected with the wires in the fanout wiring region through the transfer portions, thus improving the etching uniformity of vias.

In some examples, as shown in FIG. 29, the plurality of common electrode lines 200 is electrically connected with the common signal transmission line 300 through a plurality of connection blocks 313, and the plurality of connection blocks 313 is disposed in the same layer as the plurality of data lines 630; at least one second connection structure 720 and a connection block 313 are an integrated structure. For example, each second connection structure 720 and the corresponding connection block 313 are an integrated structure. FIG. 29 illustratively shows that the connection block 313 is electrically connected with the second conductive layer 312 through a via in the insulating layer between the connection block and the second conductive layer 312, but it is not limited thereto, and a plurality of vias can be disposed between the connection block and the second conductive layer to improve the electrical connection effect between the connection block and the common signal transmission line.

FIGS. 23-29 illustratively show that the first transmission portion 310 included in the common signal transmission line 300 can be the first transmission portion 310 with a narrow width as shown in FIG. 4, but it is not limited thereto, and the first transmission portion 31 in the present embodiment can also be the first transmission portion 310 as shown in FIG. 7 or FIG. 9. For example, the number of the fanout wiring regions 300 is N, the common signal transmission line 300 includes a first transmission portion 310 extending in the first direction and located between the display region 10 and the plurality of fanout wiring region 400, the length of the first transmission portion 310 is L, and the resistance of the part, with the length of L/2N, of the first transmission portion 310 is not greater than 30 ohms, where N is a positive integer.

For example, the common signal transmission line 300 at the intersection of the edge of the display region 10 close to the electrostatic discharge structure 500 and the edge of the display region 10 close to the gate driving structure 650 in the array substrate of the present embodiment can be the same as the structure shown in FIG. 11 or FIG. 12, and details will not be repeated here.

Another embodiment of the present disclosure provides a display panel, which includes the array substrate in any of the above embodiments.

Another embodiment of the present disclosure provides a display device, which includes the above display panel.

For example, the display device provided by the embodiment of the present disclosure can be any product or component with display function, such as a mobile phone, a tablet computer, a television, a display, a notebook computer, a digital photo frame, a navigator, a smart watch, a fitness wristband, a personal digital assistant, etc. The display device includes, but is not limited to, a RF unit, a network module, an audio output & input unit, a sensor, a user input unit, an interface unit, a memory, a processor, a power supply and other components. In addition, those skilled in the art can understand that the above-mentioned structures do not constitute a limitation to the display device provided by the embodiment of the present disclosure; in other words, the display device provided by the embodiment of the present disclosure can include more or less components, or combine some components, or have different component arrangements.

FIG. 30 is a partial structural view of a display device according to another embodiment of the present disclosure. FIG. 30 illustratively shows that the array substrate is the array substrate shown in FIG. 13, but it is not limited thereto, and the array substrate can be the array substrate in any embodiment shown in FIG. 16 or FIG. 22.

As shown in FIG. 30, the array substrate includes a first connection structure 710. The display device includes a first circuit board 2000, a second circuit board 3000, and the array substrate in any of the above-mentioned embodiments shown in FIGS. 13-29.

For example, the first circuit board 2000 can be a flexible printed circuit board (FPC). For example, the first circuit board 2000 includes a driving circuit structure 2001, the driving circuit structure 2001 can be an IC driving circuit and is configured to be electrically connected with the data lines 630.

For example, the second circuit board 3000 can be a printed circuit board (PCB).

As shown in FIG. 30, the second circuit board 3000 is electrically connected with the array substrate through the first circuit board 2000, a common signal connection line 3001 and a zero-ohm resistor 3002 are disposed on the second circuit board 3000, the zero-ohm resistor 3002 is electrically connected with the common signal connection line 3001, and the common signal connection line 3001 is electrically connected with the first connection structure 710.

For example, the zero-ohm resistor 3002 can be a jumper resistor, the zero-ohm resistor 3002 does not really have zero resistance, and the zero-ohm resistor 3002 is actually a resistor with a very small resistance. For example, the resistance of the zero ohm resistor 3002 is very close to zero.

For example, as shown in FIG. 30, the common signal connection line 3001 can be electrically connected with a pin in the second circuit board 3000, this pin is electrically connected with a pin in the first circuit board 2000, and the pin in the first circuit board 2000 is electrically connected with the bonding structure, that is electrically connected with the first connection structure 710, in the array substrate.

For example, during testing the display device, in the case where bright block occurs between adjacent fanout wiring regions 400, the zero-ohm resistor 3002 is turned off, so that the common compensation signal cannot enter the common signal transmission line 300 through the first connection structure 710, thereby reducing the difference in coupling recovery of the common voltage at different positions of the display region close to the first circuit board and effectively improving the defects of the display device.

For example, as shown in FIG. 30, the number of fanout wiring regions 400 is N, and the number of zero-ohm resistors 3002 is 2*(N−1). For example, the zero-ohm resistor 3002 at the corresponding position can be turned off according to the test result of the display device.

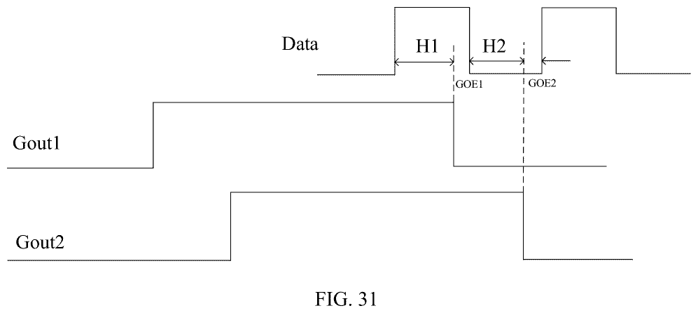

FIG. 31 is a timing chart of a data signal and a gate signal in the array substrate. As shown in FIG. 31, the charging time of one row of the display panel is equal to the actual charging time of the present row plus GOE time. When the charging time of one row is fixed, the GOE charging time is reduced and the actual charging time of the present row is increased. For example, the GOE charging time is adjusted on the premise of ensuring that the display panel is not wrongly charged. By reducing GOE, the actual charging time in one frame can be increased, the coupling recovery time of the common voltage can be prolonged, and the defects of display panel can be alleviated or even completely improved.

For example, as shown in FIG. 31, Gout1 and Gout2 are waveform diagrams of turn-on time of two rows of gate line, respectively. GOE time is the time when the data signal (Data) is delayed to rise compared with the gate signal (Gate), so as to avoid mischarging caused by gate signal delay (Gate Delay). For example, GOE1 is the overlapping time between the starting time of the falling edge of Gout1 and the starting time of the falling edge of the data signal charged into a row corresponding to Gout1, that is, Gout1 is still charged with the data signal corresponding to the Gout1 line during the delay time, thus preventing offset. In the array substrate provided by the present disclosure, the data signal (Data) can be advanced by adjusting the GOE time, that is, an achievable way; and for example, the data trigger signal (TP signal) is adjusted. When the TP signal is advanced (for example, the rising edge or falling edge of the TP signal is advanced), the TP signal is fed into the data line; and when the GOE time is reduced, the TP signal is adjusted to be advanced and the data signal is advanced.

The following statements should be noted:
(1) In the accompanying drawings of the embodiments of the present disclosure, the drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto, and the protection scope of the present disclosure should be based on the protection scope of the claims.

1. An array substrate, comprising a display region and a non-display region located on at least one side of the display region, the array substrate comprising:
a plurality of sub-pixels, wherein at least part of the plurality of sub-pixels is located in the display region, and the sub-pixels located in the display region comprise a common electrode;
a plurality of common electrode lines, located in the display region and electrically connected with the common electrode of the sub-pixels, wherein the plurality of common electrode lines is arranged along a first direction;
a common signal transmission line, disposed in the non-display region and electrically connected with the plurality of common electrode lines;
a plurality of fanout wiring regions, located in the non-display region and arrange along the first direction;
wherein, among the plurality of fanout wiring regions, a wire located in the fanout wiring region at an edge in the first direction is electrically connected with the common signal transmission line, a conductive structure is disposed between at least one fanout wiring region and the common signal transmission line, the conductive structure is electrically connected with a wire located at an edge in the at least one fanout wiring region, and the conductive structure is separated from the common signal transmission line.

2. The array substrate according to claim 1, wherein a count of conductive structures is plural, a plurality of conductive structures is arranged along the first direction, and at least one conductive structure is electrically connected with two parts of wires, close to each/other, in two adjacent fanout wiring regions.

3. The array substrate according to claim 1, further comprising:
an electrostatic discharge structure, located in the non-display region and between the common signal transmission line and the plurality of fanout wiring regions,
wherein the conductive structure is electrically connected with the electrostatic discharge structure, and the conductive structure is coupled to the common signal transmission line.

4. The array substrate according to claim 1, further comprising:
a base substrate;
a plurality of gate lines, located on the base substrate and arranged along a second direction, wherein the second direction intersects with the first direction;
a plurality of data lines, located on the base substrate and arranged along the first direction, wherein the plurality of data lines is located at one side of the plurality of gate lines away from the base substrate, and the common electrode is located at one side of the plurality of data lines away from the base substrate;
wherein the sub-pixel located in the display region further comprises a switching structure and a pixel electrode, and the switching structure comprises three electrodes electrically connected with the gate line, the data line and the pixel electrode, respectively;
the common signal transmission line comprises a first transmission portion extending in the first direction and located between the display region and the plurality of fanout wiring regions, the first transmission portion comprises a first conductive layer and a second conductive layer which are stacked, the first conductive layer is disposed in the same layer as the gate line, and the second conductive layer is disposed in the same layer as the common electrode.

5. (canceled)

6. The array substrate according to claim 4, wherein the plurality of common electrode lines is electrically connected with the first transmission portion through a plurality of connection blocks, and the plurality of connection blocks is disposed in the same layer as the plurality of data lines;
in a direction perpendicular to the base substrate, the plurality of connection blocks does not overlap with the first conductive layer, and the plurality of connection blocks is electrically connected with the first conductive layer through the second conductive layer.

7-8. (canceled)

9. The array substrate according to claim 4, wherein the common signal transmission line further comprises a second transmission portion extending in the second direction, the second transmission portion comprises a third conductive layer and a fourth conductive layer which are stacked, the third conductive layer is disposed in the same layer as the plurality of data lines, the third conductive layer and the first conductive layer are an integrated film layer, and the fourth conductive layer is disposed in the same layer as the common electrode.

10. (canceled)

11. An array substrate, comprising a display region and a non-display region located on at least one side of the display region, the array substrate comprising:
a plurality of sub-pixels, wherein at least part of the plurality of sub-pixels is located in the display region, and the sub-pixels located in the display region comprise a common electrode;
a plurality of common electrode lines, located in the display region and electrically connected with the common electrode of the sub-pixels, wherein the plurality of common electrode lines is arranged along a first direction;
a common signal transmission line, disposed in the non-display region and electrically connected with the plurality of common electrode lines;
a plurality of fanout wiring regions, located in the non-display region and arrange along the first direction;
a plurality of first connection structures, located between the common signal transmission line and the plurality of fanout wiring regions, wherein the plurality of first connection structures is arranged along the first direction;
wherein wires in at least part of the plurality of fanout wiring regions are electrically connected with the common signal transmission line through the plurality of first connection structures;
a count of the plurality of fanout wiring regions is N, the common signal transmission line comprises a first transmission portion extending in the first direction and located between the display region and the plurality of fanout wiring regions, a length of the first transmission portion is L, and a resistance of a part, with a length of L/2N, of the first transmission portion is not greater than 30 ohms, where N is a positive integer.

12. The array substrate according to claim 11, further comprising:
a base substrate;
a plurality of gate lines, located on the base substrate and arranged along a second direction, wherein the second direction intersects with the first direction;
a plurality of data lines, located on the base substrate and arranged along the first direction, wherein the plurality of data lines is located at one side of the plurality of gate lines away from the base substrate, and the common electrode is located at one side of the plurality of data lines away from the base substrate;
wherein the sub-pixel located in the display region further comprises a switching structure and a pixel electrode, and the switching structure comprises three electrodes electrically connected with the gate line, the data line and the pixel electrode, respectively;
the first transmission portion comprises a first conductive layer and a second conductive layer which are stacked, the first conductive layer is disposed in the same layer as the gate line, and the second conductive layer is disposed in the same layer as the common electrode.

13. The array substrate according to claim 12, wherein the plurality of common electrode lines is electrically connected with the first transmission portion through a plurality of connection blocks, the plurality of connection blocks do not overlap with the first conductive layer in a direction perpendicular to the base substrate, and the plurality of connection blocks is electrically connected with the first conductive layer through the second conductive layer, or the plurality of common electrode lines is electrically connected with the first transmission portion through a plurality of connection blocks, and the plurality of connection blocks is arranged in the same layer as the plurality of data lines: an orthographic projection of the plurality of connection blocks on the base substrate falls within an orthographic projection of the first conductive layer on the base substrate, and the plurality of connection blocks is electrically connected with the first conductive layer through the second conductive layer: the first transmission portion comprises a first edge and a second edge extending in the first direction, the first edge is located at one side of the second edge close to the display region, and a distance between the connection block and the second edge is less than a distance between the connection block and the first edge.

14-15. (canceled)

16. The array substrate according to claim 12, wherein the common signal transmission line further comprises a second transmission portion extending in the second direction, the second transmission portion comprises a third conductive layer and a fourth conductive layer which are stacked, the third conductive layer and the first conductive layer are an integrated film layer, and the fourth conductive layer and the second conductive layer are an integrated film layer.

17-18. (canceled)

19. The array substrate according to claim 12, wherein each fanout wiring region comprises a middle region and edge regions located at both sides of the middle region in the first direction, and the plurality of first connection structures is electrically connected with wires in the edge region of at least part of the plurality of fanout wiring regions; and
at least one first connection structure is electrically connected with wires in two edge regions, close to each other, of two adjacent fanout wiring regions.

20. The array substrate according to claim 19, further comprising:
an electrostatic discharge structure, located in the non-display region and between the common signal transmission line and the plurality of fanout wiring regions, wherein the electrostatic discharge structure comprises a plurality of electrostatic discharge unit groups, each electrostatic discharge unit group comprises a plurality of electrostatic discharge units and a connection wire connecting the plurality of electrostatic discharge units, and at least part of the plurality of electrostatic discharge units is electrically connected with the plurality of data lines, wherein the plurality of first connection structures passes through gaps between the plurality of electrostatic discharge unit groups so as to be electrically connected with the common signal transmission line, and/or the plurality of second connection structures passes through gaps between the plurality of electrostatic discharge units so as to be electrically connected with the common signal transmission line; and
at least one of the plurality of first connection structures is electrically connected with the electrostatic discharge structure.

21-23. (canceled)

24. An array substrate, comprising a display region and a non-display region located on at least one side of the display region, the array substrate comprising:
a plurality of sub-pixels, wherein at least part of the plurality of sub-pixels is located in the display region, and the sub-pixels located in the display region comprise a common electrode;
a plurality of common electrode lines, located in the display region and electrically connected with the common electrode of the sub-pixels, wherein the plurality of common electrode lines is arranged along a first direction;
a common signal transmission line, disposed in the non-display region and electrically connected with the plurality of common electrode lines;
a fanout wiring region, located in the non-display region;
a plurality of connection structures, located between the common signal transmission line and the fanout wiring region, wherein the plurality of connection structures is arranged along the first direction;
wherein the fanout wiring region comprises a middle region and edge regions located at both sides of the middle region in the first direction;
a wire in the middle region of the fanout wiring region is electrically connected with the common signal transmission line through at least one connection structure among the plurality of connection structures.

25. The array substrate according to claim 24, wherein the fanout wiring region comprises a plurality of fanout wiring regions, and each fanout wiring region comprises the middle region and the edge regions;
the plurality of connection structures comprise a plurality of first connection structures and a plurality of second connection structures, the plurality of first connection structures is arranged along the first direction, the plurality of second connection structures is arranged along the first direction, the plurality of first connection structures is electrically connected with wires in the edge region of at least part of the plurality of fanout wiring regions, and wires in the middle region of at least part of the plurality of fanout wiring regions are electrically connected with the common signal transmission line through the plurality of second connection structures;
at least one first connection structure is electrically connected with wires in two edge regions, close to each other, of two adjacent fanout wiring regions.

26. (canceled)

27. The array substrate according to claim 25, further comprising:
a base substrate;
a plurality of gate lines, located on the base substrate and arranged along a second direction, wherein the second direction intersects with the first direction;
a plurality of data lines, located on the base substrate and arranged along the first direction, wherein the plurality of data lines is located at one side of the plurality of gate lines away from the base substrate, and the common electrode is located at one side of the plurality of data lines away from the base substrate;
an electrostatic discharge structure, located in the non-display region and between the common signal transmission line and the plurality of fanout wiring regions, wherein the electrostatic discharge structure comprises a plurality of electrostatic discharge unit groups, each electrostatic discharge unit group comprises a plurality of electrostatic discharge units and a connection wire connecting the plurality of electrostatic discharge units, and at least part of the plurality of electrostatic discharge units is electrically connected with the plurality of data lines,
wherein the sub-pixel located in the display region further comprises a switching structure and a pixel electrode, and the switching structure comprises three electrodes electrically connected with the gate line, the data line and the pixel electrode, respectively;
the plurality of first connection structures passes through gaps between the plurality of electrostatic discharge unit groups so as to be electrically connected with the common signal transmission line, and the plurality of second connection structures pass through gaps between the plurality of electrostatic discharge units so as to be electrically connected with the common signal transmission line; and
at least one of the plurality of first connection structures is electrically connected with the electrostatic discharge structure.

28. The array substrate according to claim 27, wherein two electrostatic discharge units located at both sides of each second connection structure and adjacent to the each second connection structure are electrically connected with the data line;
wires in each fanout wiring region are electrically connected with one electrostatic discharge unit group, and at least one second connection structure is disposed in a plurality of gaps between the plurality of electrostatic discharge units in at least one electrostatic discharge unit group.

29. (canceled)

30. The array substrate according to claim 27, wherein the common signal transmission line comprises a first transmission portion extending in the first direction and located between the display region and the plurality of fanout wiring regions, the first transmission portion comprises a first conductive layer and a second conductive layer which are stacked, the first conductive layer is disposed in the same layer as the gate line, and the second conductive layer is disposed in the same layer as the common electrode.

31. The array substrate according to claim 30, wherein the first connection structure, the second connection structure and the first conductive layer of the common signal transmission line are an integrated structure;
the connection wire is disposed in the same layer as the first conductive layer of the common signal transmission line, and the connection wire is spaced apart from the second connection structure.

32. The array substrate according to claim 30, wherein the first connection structure and the first conductive layer of the common signal transmission line are an integrated structure, and the connection wire is disposed in the same layer as the first conductive layer of the common signal transmission line;
in a direction perpendicular to the base substrate, the second connection structure overlaps with the common signal transmission line, and the second connection structure is electrically connected with the common signal transmission line through a via in an insulating layer between the second connection structure and the common signal transmission line;
the second connection structure overlaps with the connection wire in the direction perpendicular to the base substrate: or, the plurality of common electrode lines is electrically connected with the common signal transmission line through a plurality of connection blocks, and the plurality of connection blocks is disposed in the same layer as the plurality of data lines, and at least one second connection structure and the connection block are integrated.

33-35. (canceled)

36. A display panel, comprising the array substrate according to claim 1.

37-39. (canceled)
